(19) United States
(12) Patent Application Publication
(10) Pub. No.: US 2026/0359129 A1
(43) Pub. Date: Nov. 12, 2026

(54) GRID AWARE WORKLOAD MANAGEMENT USING AVERAGE EMISSIONS

(71) Applicant: Dell Products L.P., Round Rock, TX (US)

(72) Inventors: Alyson Channing Freeman, Round Rock, TX (US); John Christian Pflueger, Jonestown, TX (US); Owen Glyn Griffiths, Dublin (IE); Richard Andrew Crisp, Austin, TX (US)

(21) Appl. No.: 19/204,585

(22) Filed: May 11, 2025

(51) Int. Cl. G06F 9/50; G06F 30/20

(52) U.S. Cl. CPC G06F 9/5038; G06F 9/505; G06F 30/20

(57) ABSTRACT

A method for managing a workload includes: receiving, by a WIE of a first IHS, a request; analyzing, by the WIE, the information to infer an execution urgency; providing, by the WIE, the request to a WS of the first IHS; obtaining, by the WS, first server DTs, and first internal factors data and first external factors data associated with a first server (FS) on the first IHS; providing, by the WS, the first server DTs, first internal factors data, and first external factors data to an IIWS; obtaining, by the IIWS, second server DTs, and second internal factors data and second external factors data associated with a second server (SS) of the second IHS; performing, by the IIWS, a set of simulations: using a model and data received from the first IHS and second IHS; determining, by the IIWS, that the SS should be executing the workload.

### BACKGROUND

As the value and use of information continues to increase, individuals and businesses seek additional ways to process and store information. One option available to users (e.g., administrators) is information handling systems (IHSs). An IHS generally processes, compiles, stores, and/or communicates information or data for business, personal, or other purposes thereby allowing users to take advantage of the value of the information. Because technology and information handling needs and requirements vary between different users or applications, IHSs may also vary regarding what information is handled, how the information is handled, how much information is processed, stored, or communicated, and how quickly and efficiently the information may be processed, stored, or communicated. The variations in IHSs allow IHSs to be general or configured for a specific user or a specific use such as financial transaction processing, airline ticket reservations, enterprise data storage, or global communications. Further, IHSs may include a variety of hardware and software components that may be configured to process, store, and communicate information and may include one or more computer systems, graphics interface systems, data storage systems, networking systems, and mobile communication systems. IHSs may also implement various virtualized architectures. Data and voice communications among IHSs may be via networks that are wired, wireless, or some combination.

### BRIEF DESCRIPTION OF DRAWINGS

Certain embodiments disclosed herein will be described with reference to the accompanying drawings. However, the accompanying drawings illustrate only certain aspects or implementations of one or more embodiments disclosed herein by way of example and are not meant to limit the scope of the claims.

FIG. 1.1A shows/illustrates a diagram of a system (that includes multiple IHSs) in accordance with one or more embodiments disclosed herein.

FIG. 1.1B shows a diagram of a system (that includes a single IHS) in accordance with one or more embodiments disclosed herein.

FIG. 1.2 shows a diagram of an IHS in accordance with one or more embodiments disclosed herein.

FIG. 1.3 shows a diagram of a digital twin (DT) creation and storage module in accordance with one or more embodiments disclosed herein.

FIG. 1.4 shows a set of DT creation templates in accordance with one or more embodiments disclosed herein.

FIG. 1.5 shows an example DT of an entity in accordance with one or more embodiments disclosed herein.

FIG. 2.1 shows a workflow of a workload instantiation engine (WIE) (for a single IHS) in accordance with one or more embodiments disclosed herein.

FIG. 2.2 shows a workflow of a workload scheduler (WS) (for a single IHS) in accordance with one or more embodiments disclosed herein.

FIG. 2.3-2.4 show a workflow of a workload lifecycle manager (WLM) and other related components of an IHS (for a single IHS) in accordance with one or more embodiments disclosed herein.

FIG. 3.1-3.2 show a workflow of a hardware management system (of an IHS) in accordance with one or more embodiments disclosed herein.

FIG. 4.1 shows a workflow of a WIE (for multiple IHSs) in accordance with one or more embodiments disclosed herein.

FIG. 4.2 shows a workflow of a WS (for multiple IHSs) in accordance with one or more embodiments disclosed herein.

FIG. 4.3 shows a workflow of an inter-IHS workload scheduler (IIWS) (for multiple IHSs) in accordance with one or more embodiments disclosed herein.

FIG. 4.4-4.5 show a workflow of a WLM and other related components of an IHS (for multiple IHSs) in accordance with one or more embodiments disclosed herein.

FIG. 5 shows a diagram of a computing device in accordance with one or more embodiments disclosed herein.

### DETAILED DESCRIPTION

Specific embodiments disclosed herein will now be described in detail with reference to the accompanying figures. In the following detailed description of the embodiments disclosed herein, numerous specific details are set forth in order to provide a more thorough understanding of one or more embodiments disclosed herein. However, it will be apparent to one of ordinary skill in the art that the one or more embodiments disclosed herein may be practiced without these specific details. In other instances, well-known features have not been described in detail to avoid unnecessarily complicating the description.

In the following description of the figures, any component described with regard to a figure, in various embodiments disclosed herein, may be equivalent to one or more like-named components described with regard to any other figure. For brevity, descriptions of these components will not be repeated with regard to each figure. Thus, each and every embodiment of the components of each figure is incorporated by reference and assumed to be optionally present within every other figure having one or more like-named components. Additionally, in accordance with various embodiments disclosed herein, any description of the components of a figure is to be interpreted as an optional embodiment, which may be implemented in addition to, in conjunction with, or in place of the embodiments described with regard to a corresponding like-named component in any other figure.

Throughout this application, elements of figures may be labeled as A to N. As used herein, the aforementioned labeling means that the element may include any number of items, and does not require that the element include the same number of elements as any other item labeled as A to N. For example, a data structure may include a first element labeled as A and a second element labeled as N. This labeling convention means that the data structure may include any number of the elements. A second data structure, also labeled as A to N, may also include any number of elements. The number of elements of the first data structure, and the number of elements of the second data structure, may be the same or different.

Throughout the application, ordinal numbers (e.g., first, second, third, etc.) may be used as an adjective for an element (i.e., any noun in the application). The use of ordinal numbers is not to imply or create any particular ordering of the elements nor to limit any element to being only a single element unless expressly disclosed, such as by the use of the terms “before”, “after”, “single”, and other such terminology. Rather, the use of ordinal numbers is to distinguish between the elements. By way of an example, a first element is distinct from a second element, and the first element may encompass more than one element and succeed (or precede) the second element in an ordering of elements.

As used herein, the phrase operatively connected, or operative connection, means that there exists between elements/components/devices a direct or indirect connection that allows the elements to interact with one another in some way. For example, the phrase “operatively connected” may refer to any direct connection (e.g., wired directly between two devices or components) or indirect connection (e.g., wired and/or wireless connections between any number of devices or components connecting the operatively connected devices). Thus, any path through which information may travel may be considered an operative connection.

In recent years, the increasing energy usage/consumption of IHSs (e.g., data centers, infrastructure nodes, etc.), operating costs of IHSs, and significant environmental impacts of IHSs have made the users (e.g., owners, administrators, operators, etc.) of IHSs concerned about the future of IHSs. Currently, IHSs are typically managed locally, with operators not considering external factors (e.g., environmental factors, power grid conditions, outside conditions, etc.) in their IHS management considerations, which may cause missed opportunities to reduce, at least, energy usage, operating costs, and significant environmental impacts of IHSs. For example, without considering external factors, workloads tackling scientific problems can be at risk due to unstable outside conditions (e.g., a sudden change in weather conditions) as these problems incorporate calculation chains that, when interrupted, may result in a complete loss of work.

Further, managing an information technology component (ITC) (e.g., an IHS (and its components), a networking device that is part of a network, etc.) may require the involvement of different administrators/stakeholders within a corresponding organization. The degree of influence (knowingly or unknowingly) a stakeholder may have on an organization's overall IT architecture may be different from his/her technical understanding of the IT architecture, especially in multi-cloud IT frameworks where IT-related decision making is no longer under the oversight/control of a singular team.

Beyond that, from a management perspective, organizations are at risk (or facing with difficulties) while operating multiple systems in parallel (e.g., across multi cloud(s) and/or on-premises frameworks), especially reporting and/or forecasting IT-related activities (due to opaque and disjointed components used during operation). This prevents stakeholders to make a centralized decision, develop strategies, and/or ensure user/customer data security.

In addition, the relative intensity of a workload (e.g., a compute task) may be sensitive to the associated computing resource utilization, in which, in general, a workload that is being executed on a low-utilized server may have a higher negative environmental impact(s). In view of this, an optimized workload management (across, for example, IHSs of a related organization) may need to be implemented (by, at least, managing latency and urgency/priority of workloads) to minimize these impacts (which may depend on average grid emissions (or average emissions) while executing a related workload).

For at least the reasons discussed above and without requiring resource-intensive efforts (e.g., time, engineering, etc.), a fundamentally different solution/framework is needed (e.g., a framework for time-and location-shifting of a workload (e.g., an urgent workload, a non-urgent workload, etc.) using forecasted average “grid” emissions data, in order to, at least, enhance a corresponding IHS′ efficiency and sustainability).

Embodiments disclosed herein relate to methods and systems to perform intelligent workload/operation management. As a result of the processes discussed below, one or more embodiments disclosed herein advantageously ensure that: (i) the framework obtains/retrieves real-time (or near-real-time) internal factors data (e.g., information obtained from IHSs regarding computing resource availability, quantity, viability, current energy losses in an IHS due to power distribution across the IHS, cooling system energy requirements of the IHS′ cooling system, etc.) and external factors data (e.g., forecasted average emissions, information with respect to obtaining power/energy over a period of time, forecasted weather data, forecasted climate data, etc.) from corresponding entities, and uses the aforementioned data to make more informed decisions for workload scheduling/deployment; (ii) the framework can manage one or more workloads in terms of scheduling/deployment (e.g., a workload scheduler can manage multiple workloads that are received from one or more users and make informed decisions to schedule each workload accordingly); (iii) using one or more feedback loops, the framework can re-train (and/or fine-tune) machine learning (ML)/artificial intelligence (AI) models (that are used by the workload scheduler to manage workloads) to improve a related model's accuracy (in terms of producing better forecasting outcomes); (iv) the framework implements role-specific user interfaces (e.g., graphical user interfaces (GUIs), portals, etc.), which present and contextualize information (e.g., information with respect to workloads, servers, IHSs, etc.) in accordance with a user's “operational” role/level; and/or (v) over time and based on previous user interactions, the framework tailors (using a retrieval-augmented generation (RAG) engine) each UI to generate UIs that better align with each user/stakeholder and his/her areas of interest.

The following describes various embodiments disclosed herein.

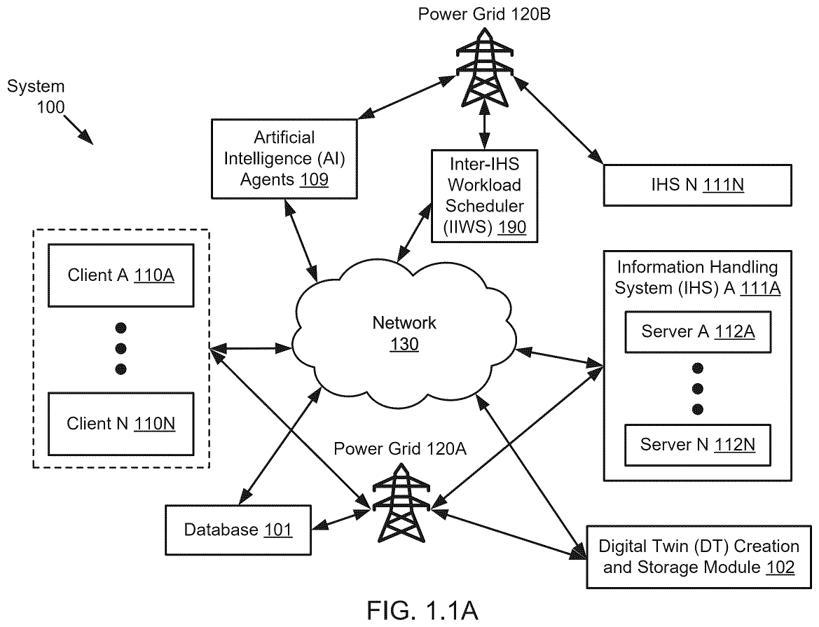

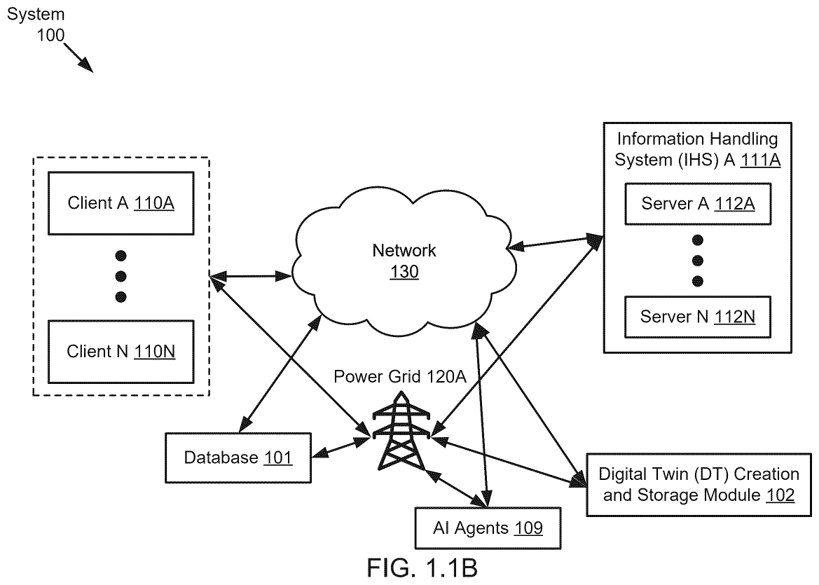

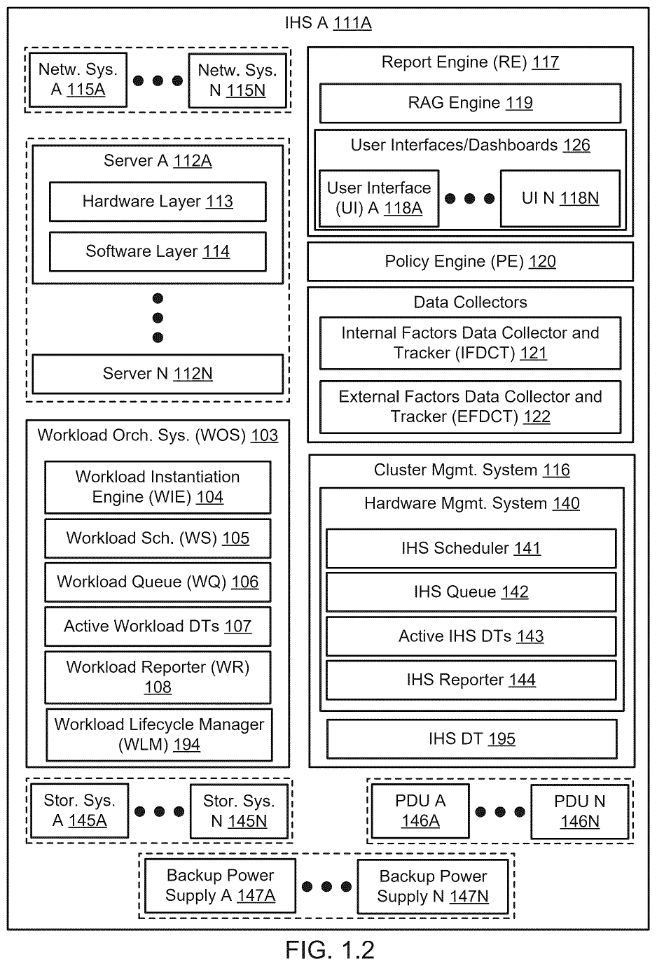

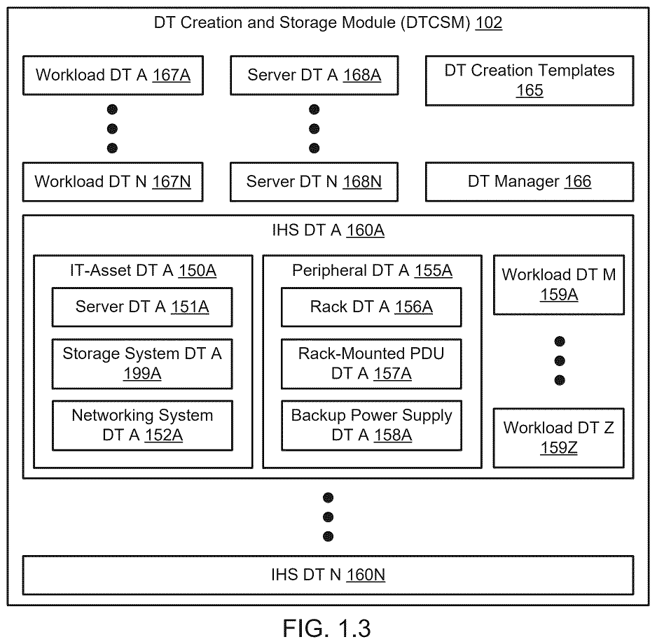

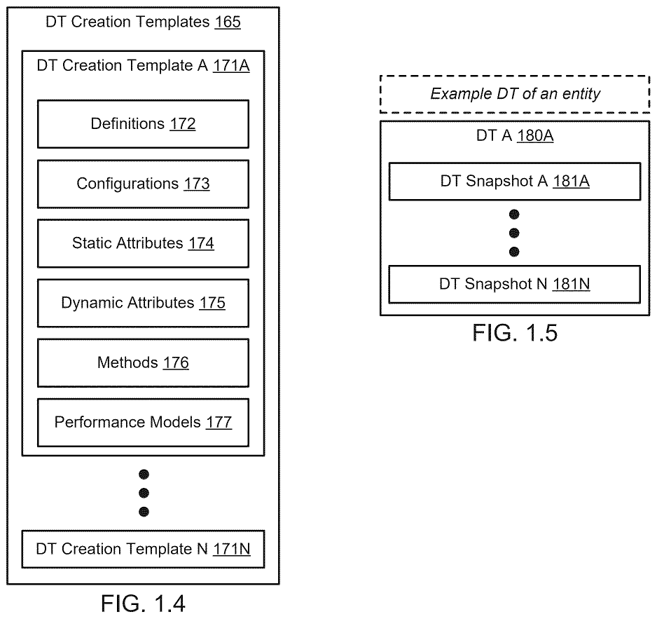

FIG. 1.1A shows a diagram of a system (100) (that includes multiple IHSs) in accordance with one or more embodiments disclosed herein. The system (100) includes any number of clients (e.g., Client A (110A), Client N (110N), etc.), a database (101), any number of IHSs/nodes (e.g., IHS A (111A), IHS N (111N), etc.), a network (130), any number of power grids (e.g., 120A, 120B, etc.), any number of AI agents (e.g., 109), an IIWS (190), and a DT creation and storage module (DTCSM) (102). The system (100) may include additional, fewer, and/or different components without departing from the scope of the embodiments disclosed herein. Each component may be operably/operatively connected to any of the other components via any combination of wired and/or wireless connections. Each component illustrated in FIG. 1.1A is discussed below.

In one or more embodiments, the clients (e.g., 110A, 110N, etc.), the database (101), the IHSs (e.g., 111A, 111N, etc.), the network (130), the power grids (e.g., 120A, 120B, etc.), the AI agents (e.g., 109), the IIWS (190), and the DTCSM (102) may be (or may include) physical hardware or logical devices, as discussed below. While FIG. 1.1A shows a specific configuration of the system (100), other configurations may be used without departing from the scope of the embodiments disclosed herein. For example, although the clients (e.g., 110A, 110N, etc.) and the IHSs (e.g., 111A, 111N, etc.) are shown to be operatively connected through a communication network (e.g., 130), the clients (e.g., 110A, 110N, etc.) and the IHSs (e.g., 111A, 111N, etc.) may be directly connected (e.g., without an intervening communication network). As yet another example, refer to FIG. 1.1B.

As yet another example, although (i) the clients (e.g., 110A, 110N, etc.) and an IHS (not shown) can be considered as deployed to a “functional edge region” of the system (100) (as edge devices), (ii) the IHSs (e.g., 111A, 111N, etc.) can be considered as deployed to a “far edge region” of the system (100) (as edge nodes), and (iii) the DTCSM (102) and the database (101) can be considered as deployed to a “near edge region” of the system (100), the system (100) may include another region (e.g., another logical layer) in between the far edge region and the near edge region.

As yet another example, in one embodiment, a functional edge region (where the actual functioning happens such as, for example, a user uses a client to make a product or to deliver a service), a far edge region (including, at least, compute, storage, and/or network access devices focused on data acquisition and processing), and a near edge region of the system (100) may be co-located in one site/factory, and, in another embodiment, the functional edge and far edge regions may be co-located in one site and the near edge region may represent a “cloud” environment (or a cloud computing environment). In this example, the near edge region may be far away from the functional edge and far edge regions, where the near edge region may represent a centralized and geographically distant cloud environment (e.g., an environment that is hundreds of miles away from the site). Further, in this example, the database (101) and the DTCSM (102) may be some of the cloud devices that execute on the cloud environment.

Further, in the aforementioned example, even though the functional edge and far edge regions are described as co-located in one site and the near edge region is described as representing a cloud environment, the system (100) may include another region/layer (e.g., a fog layer) in between the far edge region and near edge region. In one or more embodiments, the fog layer may include one or more “fog” devices, similar to IHS A (111A), in which both the fog devices and IHS A (111A) perform distributed computing and focus on the physical deployment of compute and storage resources in relation to data that is being produced (e.g., the difference is a matter of where those resources are located such as edge computing refers to computational processes being done at or near the “edge” of an Internet of Things (IoT) network, whereas fog computing refers to the network connections between an edge node (e.g., 111N) and a cloud device (e.g., 101) to extend the cloud device closer to the edge of the IoT network).

In one or more embodiments, each component (e.g., 110A, 101, 102, 120A, 111A, etc.) of the system (100) may be part of a business operation region (BOR) (not shown) of an organization, in which the BOR corresponds to a geographic region (e.g., a zone, a city, a county, a state, a province, a country, a country grouping (e.g., the European Union), etc.). For example, IHS A (111A) of Organization X may be located in Austin, Texas and IHS N (111N) of Organization X may be located in the Netherlands, in which Organization X has multiple geographically distributed IHSs (e.g., edge nodes) around the world.

In one or more embodiments, in one architecture (e.g., the “unidirectional” architecture), one of the edge nodes (e.g., the parent edge node) of an organization may be deployed to the United States, which serves (e.g., shares) data to/among the remaining edge nodes (e.g., the child edge nodes that are deployed to Argentina, India, and France) of the organization. In this architecture, the child edge nodes may transmit their data to the parent edge node so that the parent edge node stays updated. Thereafter, the parent edge node may distribute/forward received data to the child edge nodes to keep the child edge nodes equally updated.

In another architecture (e.g., the “bidirectional” architecture), one of the edge nodes of an organization may be deployed to Greece and the other one may be deployed to Spain, in which both edge nodes know each other and when a data change is occurred in one of them, the other edge node may automatically obtain that data to stay updated.

In another architecture (e.g., the “multidirectional” architecture), an organization may have multiple edge nodes deployed around the world and all the edge nodes know each other. When one of the edge nodes is updated (e.g., when that edge node receives a software package), the remaining edge nodes are updated accordingly (e.g., by sending a data transfer request to each of the remaining edge nodes).

In one or more embodiments, the functioning of the clients (e.g., 110A, 110N, etc.) and the IHSs (e.g., 111A, 111N, etc.) is not dependent upon the functioning and/or existence of the other components (e.g., devices) in the system (100). Rather, the clients and the IHSs may function independently and perform operations locally that do not require communication with other components. Accordingly, embodiments disclosed herein should not be limited to the configuration of components shown in FIG. 1.1A.

As used herein, “communication” may refer to simple data passing, or may refer to two or more components coordinating a job. As used herein, the term “data” is intended to be broad in scope. In this manner, that term embraces, for example (but not limited to): a data stream (or stream data), data chunks, data blocks, atomic data, emails, objects of any type, files of any type (e.g., media files, spreadsheet files, database files, etc.), contacts, directories, sub-directories, volumes, etc.

As used herein, a “volume” may be analogous to a logical unit number in a storage area network (SAN), in which a volume may be a subset of the database's (101) capacity presented by a node of the database as a local block device. A volume's data may be evenly distributed across all storage resources of the database (101), for example, according to a data layout selected for the database (101).

In one or more embodiments, although terms such as “document”, “file”, “segment”, “block”, or “object” may be used by way of example, the principles of the present disclosure are not limited to any particular form of representing and storing data or other information. Rather, such principles are equally applicable to any object capable of representing information.

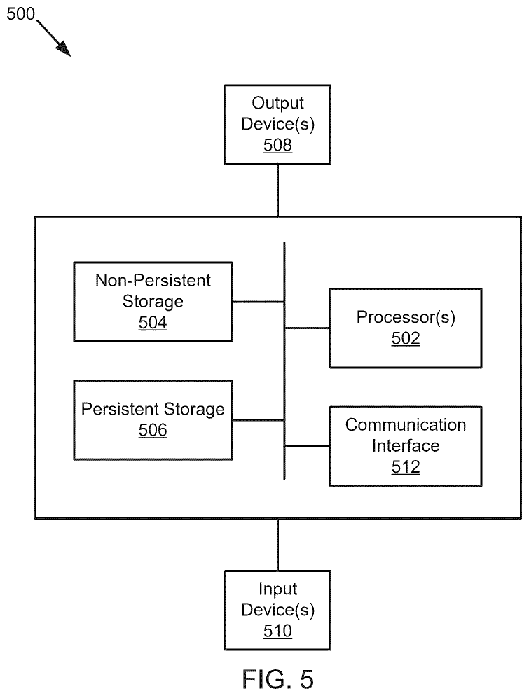

In one or more embodiments, the system (100) may be a distributed system (e.g., a data processing environment) and may deliver at least computing power (e.g., real-time (on the order of milliseconds (ms) or less) network monitoring, server virtualization, data deduplication, etc.), storage capacity (e.g., data backup), and data protection (e.g., software-defined data protection, disaster recovery, etc.) as a service to users (e.g., people, tenants, etc.) of clients (e.g., 110A, 110N, etc.). For example, the system (100) may be configured to organize unbounded, continuously generated data into a data stream. The system (100) may also represent a comprehensive middleware layer executing on computing devices (e.g., 500, FIG. 5) that supports application and storage environments.

In one or more embodiments, the system (100) may support one or more virtual machine (VM) environments, and may map capacity requirements (e.g., computational load, storage access, etc.) of VMs and supported applications to available resources (e.g., processing resources, storage resources, etc.) managed by the environments. Further, the system (100) may be configured for workload placement collaboration and computing resource (e.g., processing, storage/memory, virtualization, networking, etc.) exchange.

To provide computer-implemented services to the users, the system (100) may perform some computations (e.g., data collection, distributed processing of collected data, etc.) locally (e.g., at the users'site using the clients (e.g., 110A, 110N, etc.)) and other computations remotely (e.g., away from the users'site using the IHSs (e.g., 111A, 111N, etc.)) from the users. By doing so, the users may utilize different computing devices (e.g., 500, FIG. 5) that have different quantities of computing resources (e.g., processing cycles, memory, storage, etc.) while still being afforded consistent user experience. For example, by performing some computations remotely, the system (100) (i) may maintain the consistent user experience provided by different computing devices even when the different computing devices possess different quantities of computing resources, and (ii) may process data more efficiently in a distributed manner by avoiding the overhead associated with data distribution and/or command and control via separate connections.

As used herein, “computing” refers to any operations that may be performed by a computer, including (but not limited to): computation, data storage, data retrieval, communications, etc. Further, as used herein, a “computing device” refers to any device in which a computing operation may be carried out. A computing device may be, for example (but not limited to): a compute component, a storage component, a network device, a telecommunications component, etc.

As used herein, a “resource” refers to any program, application, document, file, asset, executable program file, desktop environment, computing environment, or other resource made available to, for example, a user/customer of a client (described below). The resource may be delivered to the client via, for example (but not limited to): conventional installation, a method for streaming, a VM executing on a remote computing device, execution from a removable storage device connected to the client (such as universal serial bus (USB) device), etc.

In one or more embodiments, a client (e.g., 110A, 110N, etc.) may include functionality to, e.g.,: (i) capture sensory input (e.g., sensor data) in the form of text, audio, video, touch or motion, (ii) collect massive amounts of data at the edge of an IoT network (where, the collected data may be grouped as: (a) data that needs no further action and does not need to be stored, (b) data that should be retained for later analysis and/or record keeping, and (c) data that requires an immediate action/response), (iii) provide to other entities (e.g., IHS A (111A), the database (101), etc.), store, or otherwise utilize captured sensor data (and/or any other type and/or quantity of data), (iv) provide surveillance services (e.g., determining object-level information, performing face recognition, etc.) for scenes (e.g., a physical region of space), (v) initiate AI/ML model training and/or AI inferencing applications on one or more IHSs (e.g., 111A, 111N, etc.), (vi) monitor the status of the AI model training and/or receive the results of AI inferencing applications, and/or (vii) be used by any number of users for initiating and executing workloads. One of ordinary skill will appreciate that the client may perform other functionalities without departing from the scope of the embodiments disclosed herein.

In one or more embodiments, the clients (e.g., 110A, 110N, etc.) may be geographically distributed devices (e.g., user devices, front-end devices, etc.) and may have relatively restricted hardware and/or software resources when compared to the IHSs (e.g., 111A, 111N, etc.). As being, for example, a sensing device, each of the clients may be adapted to provide monitoring services. For example, a client may monitor the state of a scene (e.g., objects disposed in a scene). The monitoring may be performed by obtaining sensor data from sensors that are adapted to obtain information regarding the scene, in which a client may include and/or be operatively coupled to one or more sensors (e.g., a physical device adapted to obtain information regarding one or more scenes).

In one or more embodiments, the sensor data may be any quantity and types of measurements (e.g., of a scene's properties, of an environment's properties, etc.) over any period(s) of time and/or at any points-in-time (e.g., any type of information obtained from one or more sensors, in which different portions of the sensor data may be associated with different periods of time (when the corresponding portions of sensor data were obtained)). The sensor data may be obtained using one or more sensors. The sensor may be, for example (but not limited to): a visual sensor (e.g., a camera adapted to obtain optical information (e.g., a pattern of light scattered off of the scene) regarding a scene/environment), an audio sensor (e.g., a microphone adapted to obtain auditory information (e.g., a pattern of sound from the scene) regarding a scene), an electromagnetic radiation sensor (e.g., an infrared sensor), a chemical detection sensor, a temperature sensor, a humidity sensor, a count sensor, a distance sensor, a global positioning system sensor, a biological sensor, a differential pressure sensor, a corrosion sensor, etc.

In one or more embodiments, the clients (e.g., 110A, 110N, etc.) may be physical or logical computing devices configured for hosting one or more workloads, or for providing a computing environment whereon workloads may be implemented. The clients may provide computing environments that are configured for, at least: (i) workload placement collaboration, (ii) computing resource (e.g., processing, storage/memory, virtualization, networking, etc.) exchange, and (iii) protecting workloads (including their applications and application data) of any size and scale (based on, for example, one or more service level agreements (SLAs) configured by users of the clients). The clients (e.g., 110A, 110N, etc.) may correspond to computing devices that one or more users use to interact with one or more components of the system (100).

In one or more embodiments, a client (e.g., 110A, 110N, etc.) may represent a physical appliance or a computing device operated by one or more individuals of (or employed by) an organization. Examples of said individual(s) may include, but not limited to, any organization executive(s) (e.g., chief executive officer (CEO), chief financial officer (CFO), etc.), and any employee(s) in the accounting/finance team of the organization (e.g., a collector person). Further, the organization may refer to any enterprise at least engaged in for-profit commercial, industrial, or professional activities.

In one or more embodiments, a client (e.g., 110A, 110N, etc.) may include any number of applications (and/or content accessible through the applications) that provide computer-implemented services to a user. Applications may be designed and configured to perform one or more functions instantiated by a user of the client. In order to provide application services, each application may host similar or different components. The components may be, for example (but not limited to): instances of databases, instances of email servers, etc. Applications may be executed on one or more clients as instances of the application.

Applications may vary in different embodiments, but in certain embodiments, applications may be custom developed or commercial (e.g., off-the-shelf) applications that a user desires to execute in a client (e.g., 110A, 110N, etc.). In one or more embodiments, applications may be logical entities executed using computing resources of a client. For example, applications may be implemented as computer instructions stored on persistent storage of the client that when executed by the processor(s) of the client, cause the client to provide the functionality of the applications described throughout the application.

In one or more embodiments, while performing, for example, one or more operations requested by a user, applications installed on a client (e.g., 110A, 110N, etc.) may include functionality to request and use physical and logical resources of the client. Applications may also include functionality to use data stored in storage/memory resources of the client. The applications may perform other types of functionalities not listed above without departing from the scope of the embodiments disclosed herein. While providing application services to a user, applications may store data that may be relevant to the user in storage/memory resources of the client.

In one or more embodiments, to provide services to the users, the clients (e.g., 110A, 110N, etc.) may utilize, rely on, or otherwise cooperate with the IHSs (e.g., 111A, 111N, etc.) and/or the database (101). For example, the clients may issue requests to IHS A (111A) to receive responses and interact with various components of IHS A (111A). The clients may also request data from and/or send data to IHS A (111A) (for example, the clients may transmit information to IHS A that allows IHS A to perform computations, the results of which are used by the clients to provide services to the users). As yet another example, the clients may utilize computer-implemented services provided by IHS N (111N). When the clients interact with IHS N (111N), data that is relevant to the clients may be stored (temporarily or permanently) in IHS N.

In one or more embodiments, a client (e.g., 110A, 110N, etc.) may be capable of, e.g.,: (i) collecting users'inputs, (ii) correlating collected users'inputs to the computer-implemented services to be provided to the users, (iii) communicating with the IHSs (e.g., 111A, 111N, etc.) and/or the database (101) that perform computations necessary to provide the computer-implemented services, (iv) using the computations performed by, for example, IHS A (111A) to provide the computer-implemented services in a manner that appears (to the users) to be performed locally to the users, and/or (v) communicating with any virtual desktop (VD) in a virtual desktop infrastructure (VDI) environment (or a virtualized architecture) provided by the servers (using any known protocol in the art), for example, to exchange remote desktop traffic or any other regular protocol traffic (so that, once authenticated, users may remotely access independent VDs).

As described above, the clients (e.g., 110A, 110N, etc.) may provide computer-implemented services to users (and/or other computing devices). The clients may provide any number and any type of computer-implemented services. To provide computer-implemented services, each client may include a collection of physical components (e.g., processing resources, storage/memory resources, networking resources, etc.) configured to perform operations of the client and/or otherwise execute a collection of logical components (e.g., virtualization resources) of the client.

In one or more embodiments, a processing resource (not shown) may refer to a measurable quantity of a processing-relevant resource type, which can be requested, allocated, and consumed. A processing-relevant resource type may encompass a physical device (i.e., hardware), a logical intelligence (i.e., software), or a combination thereof, which may provide processing or computing functionality and/or services. Examples of a processing-relevant resource type may include (but not limited to): a central processing unit (CPU), a graphics processing unit (GPU), a data processing unit (DPU), a computation acceleration resource, an application-specific integrated circuit (ASIC), a digital signal processor for facilitating high speed communication, etc.

In one or more embodiments, a storage or memory resource (not shown) may refer to a measurable quantity of a storage/memory-relevant resource type, which can be requested, allocated, and consumed (for example, to store sensor data and provide previously stored data). A storage/memory-relevant resource type may encompass a physical device, a logical intelligence, or a combination thereof, which may provide temporary or permanent data storage functionality and/or services. Examples of a storage/memory-relevant resource type may be (but not limited to): a hard disk drive (HDD), a solid-state drive (SSD), random access memory (RAM), Flash memory, a tape drive, a fibre-channel (FC) based storage device, a floppy disk, a diskette, a compact disc (CD), a digital versatile disc (DVD), a non-volatile memory express (NVMe) device, a NVMe over Fabrics (NVMe-oF) device, resistive RAM (ReRAM), persistent memory (PMEM), virtualized storage, virtualized memory, etc.

In one or more embodiments, while the clients (e.g., 110A, 110N, etc.) provide computer-implemented services to users, the clients may store data that may be relevant to the users to the storage/memory resources. When the user-relevant data is stored (temporarily or permanently), the user-relevant data may be subjected to loss, inaccessibility, or other undesirable characteristics based on the operation of the storage/memory resources.

To mitigate, limit, and/or prevent such undesirable characteristics, users of the clients (e.g., 110A, 110N, etc.) may enter into agreements (e.g., SLAs) with providers (e.g., vendors) of the storage/memory resources. These agreements may limit the potential exposure of user-relevant data to undesirable characteristics. These agreements may, for example, require duplication of the user-relevant data to other locations so that if the storage/memory resources fail, another copy (or other data structure usable to recover the data on the storage/memory resources) of the user-relevant data may be obtained. These agreements may specify other types of activities to be performed with respect to the storage/memory resources without departing from the scope of the embodiments disclosed herein.

In one or more embodiments, a networking resource (not shown) may refer to a measurable quantity of a networking-relevant resource type, which can be requested, allocated, and consumed. A networking-relevant resource type may encompass a physical device, a logical intelligence, or a combination thereof, which may provide network connectivity functionality and/or services. Examples of a networking-relevant resource type may include (but not limited to): a network interface card (NIC), a network adapter, a network processor, etc.

In one or more embodiments, a networking resource may provide capabilities to interface a client with external entities (e.g., IHS A (111A), the database (101), etc.) and to allow for the transmission and receipt of data with those entities. A networking resource may communicate via any suitable form of wired interface (e.g., Ethernet, fiber optic, serial communication etc.) and/or wireless interface, and may utilize one or more protocols (e.g., transport control protocol (TCP), user datagram protocol (UDP), RDMA, RDMA over Converged Ethernet (RoCE), IEEE 801.11, etc.) for the transmission and receipt of data.

In one or more embodiments, a networking resource may implement and/or support the above-mentioned protocols to enable the communication between the client and the external entities. For example, a networking resource may enable the client to be operatively connected, via Ethernet, using a TCP protocol to form a “network fabric”, and may enable the communication of data between the client and the external entities. In one or more embodiments, each client may be given a unique identifier (e.g., an Internet Protocol (IP) address) to be used when utilizing the above-mentioned protocols.

Further, a networking resource, when using a certain protocol or a variant thereof, may support streamlined access to storage/memory media of other clients (e.g., 110A, 110N, etc.). For example, when utilizing Remote DMA (“RDMA”), e.g., RoCE to access data on another client, it may not be necessary to interact with the logical components of that client. Rather, when using RDMA, it may be possible for the networking resource to interact with the physical components of that client to retrieve and/or transmit data, thereby avoiding any higher-level processing by the logical components executing on that client.

In one or more embodiments, a virtualization resource (not shown) may refer to a measurable quantity of a virtualization-relevant resource type (e.g., a virtual hardware component), which can be requested, allocated, and consumed, as a replacement for a physical hardware component. A virtualization-relevant resource type may encompass a physical device, a logical intelligence, or a combination thereof, which may provide computing abstraction functionality and/or services. Examples of a virtualization-relevant resource type may include (but not limited to): a virtual server, a VM, a container, a virtual CPU (vCPU), a virtual storage pool, etc.

In one or more embodiments, a virtualization resource may include a hypervisor (e.g., a VM monitor), in which the hypervisor may be configured to orchestrate an operation of, for example, a VM by allocating computing resources of a client (e.g., 110A, 110N, etc.) to the VM. In one or more embodiments, the hypervisor may be a physical device including circuitry. The physical device may be, for example (but not limited to): a field-programmable gate array (FPGA), an application-specific integrated circuit, a programmable processor, a microcontroller, a digital signal processor, etc. The physical device may be adapted to provide the functionality of the hypervisor. Alternatively, in one or more of embodiments, the hypervisor may be implemented as computer instructions stored on storage/memory resources of the client that when executed by processing resources of the client, cause the client to provide the functionality of the hypervisor.

In one or more embodiments, a client (e.g., 110A, 110N, etc.) may be, for example (but not limited to): a physical computing device, a smartphone, a tablet, a wearable, a gadget, a closed-circuit television (CCTV) camera, a music player, a game controller, etc. Different clients may have different computational capabilities. In one or more embodiments, Client A (110A) may have 16 GB of dynamic RAM (DRAM) and 1 CPU with 12 cores, whereas Client N (110N) may have 8 GB of PMEM and 1 CPU with 16 cores. Other different computational capabilities of the clients not listed above may also be considered without departing from the scope of the embodiments disclosed herein.

Further, in one or more embodiments, a client (e.g., 110A, 110N, etc.) may be implemented as a computing device (e.g., 500, FIG. 5). The computing device may be, for example, a desktop computer, a server, a distributed computing system, or a cloud resource. The computing device may include one or more processors, memory (e.g., RAM), GPUs, and persistent storage (e.g., HDDs, SSDs, etc.). The computing device may include instructions, stored in the persistent storage, that when executed by the processor(s) of the computing device cause the computing device to perform the functionality of the client described throughout the application.

Alternatively, in one or more embodiments, the client (e.g., 110A, 110N, etc.) may be implemented as a logical device (e.g., a VM, an application executing on one or more hardware components, etc.). The logical device may utilize the computing resources of any number of computing devices to provide the functionality of the client described throughout this application.

In one or more embodiments, users (e.g., administrators, organization executives, customers, people, etc.) may interact with (or operate) the clients (e.g., 110A, 110N, etc.) in order to perform work-related tasks (e.g., production workloads). In one or more embodiments, the accessibility of users to the clients may depend on a regulation set by an administrator of the clients. To this end, each user may have a personalized user account that may, for example, grant access to certain data, applications, and computing resources of the clients. This may be realized by implementing virtualization technology. In one or more embodiments, an administrator may be a user with permission (e.g., a user that has root-level access) to make changes to the clients that would affect other users of the clients.

In one or more embodiments, for example, a user may be automatically directed to a login screen of a client when the user connected to that client. Once the login screen of the client is displayed, the user may enter credentials (e.g., username, password, etc.) of the user on the login screen. The login screen may be a GUI generated by a visualization module (not shown) of the client. In one or more embodiments, the visualization module may be implemented in hardware (e.g., circuitry), software, or any combination thereof.

In one or more embodiments, a GUI may be displayed on a display of a computing device (e.g., 500, FIG. 5) using functionalities of a display engine (not shown), in which the display engine is operatively connected to the computing device. The display engine may be implemented using hardware (or a hardware component), software (or a software component), or any combination thereof. The login screen may be displayed in any visual format that would allow the user to easily comprehend (e.g., read and parse) the listed information.

In one or more embodiments, an IHS of the IHSs (e.g., 111A, 111N, etc.) may include functionality to (using one or more servers), e.g.,: (i) obtain (or receive) data (e.g., any type and/or quantity of input) from any source (and, if necessary, aggregate the data); (ii) process/analyze data that is received from one or more clients (e.g., 110A, 110N, etc.) to generate additional data that is derived from the obtained data without experiencing any middleware and hardware limitations; (iii) provide meaningful information (e.g., a response) back to the corresponding clients; (iv) filter data (e.g., received from a client) before pushing the data (and/or the derived data) to the storage for management of the data and/or for storage of the data (while pushing the data, the IHS may include information regarding a source of the data (e.g., an identifier of the source) so that such information may be used to associate provided data with one or more of the users (or data owners)); (v) host and maintain various workloads; (vi) provide a computing environment whereon workloads may be implemented (e.g., employing linear, non-linear, and/or AI/ML models to perform cloud-based data processing); (vii) incorporate strategies (e.g., strategies to provide VDI capabilities) for remotely enhancing capabilities of the clients; (viii) provide robust security features to the clients and make sure that a minimum level of service is always provided to a user of a client; (ix) transmit the result(s) of the computing work performed (e.g., real-time business insights, equipment maintenance predictions, other actionable responses, etc.) to another IHS for review and/or other human interactions; (x) exchange data with other devices registered in/to the network (130) in order to, for example, participate in a collaborative workload placement (e.g., the IHS may split up a request (e.g., an operation, a task, an activity, etc.) with another IHS, coordinating its efforts to complete the request more efficiently than if the IHS had been responsible for completing the request); (xi) provide software-defined data protection for the clients (e.g., 110A, 110N, etc.); (xii) provide automated data discovery, protection, management, and recovery operations for the clients; (xiii) monitor operational states of the clients; (xiv) regularly back up configuration information of the clients to a storage system (not shown); (xv) provide (e.g., via a broadcast, multicast, or unicast mechanism) information (e.g., a location identifier, the amount of available resources, etc.) associated with the IHS to other IHSs of the system (100); (xvi) configure or control any mechanism that defines when, how, and what data to provide to the clients and/or to the database; (xvii) provide data deduplication to the clients (in conjunction with the storage system); (xviii) orchestrate data protection through one or more GUIs; (xix) empower data owners (e.g., users of the clients) to perform self-service data backup and restore operations from their native applications; (xx) ensure compliance and satisfy different types of service level objectives (SLOs) set by an administrator/user; (xxi) increase resiliency of an organization by enabling rapid recovery or cloud disaster recovery from cyber incidents; (xxii) provide operational simplicity, agility, and flexibility for physical, virtual, and cloud-native environments; (xxiii) consolidate multiple data process or protection requests (received from, for example, clients) so that duplicative operations (which may not be useful for restoration purposes) are not generated; (xxiv) initiate multiple data process or protection operations in parallel (e.g., an IHS may host multiple operations, in which each of the multiple operations may (a) manage the initiation of a respective operation and (b) operate concurrently to initiate multiple operations); and/or (xxv) manage operations of one or more clients (e.g., receiving information from the clients regarding changes in the operation of the clients) to improve their operations (e.g., improve the quality of data being generated, decrease the computing resources cost of generating data, etc.). In one or more embodiments, in order to read, write, or store data, the IHS (e.g., 111A, 111N, etc.) may communicate with, for example, the database (101) and/or other storage devices in the system (100).

In one or more embodiments, because technology and information handling needs vary between different users or applications, IHSs (e.g., 111A, 111N, etc.) may also vary regarding what information/data is handled, how the information is handled, how much information is processed, stored, or communicated, and how quickly and efficiently the information may be processed, stored, or communicated. The variations in IHSs may allow for the IHSs to be general or configured for a specific user or specific use such as financial transaction processing, airline reservations, enterprise data storage, or global communications. In addition, IHSs (e.g., 111A, 111N, etc.) may include a variety of hardware and software components that may be configured to process, store, and communicate information and may include one or more computer systems, data storage systems, and networking systems.

As described above, an IHS (e.g., 111A, 111N, etc.) may be capable of providing a range of functionalities/services to the users of the clients (e.g., 110A, 110N, etc.). However, not all users may be allowed to receive all the services. To manage the services provided to the users of the clients, a service manager (not shown) in accordance with embodiments disclosed herein may manage the operation of the network (130), in which the clients are operably connected to the IHSs over the network. Specifically, the service manager (i) may identify services to be provided by the IHSs (for example, based on the number of users using the clients) and (ii) may limit communications of the clients to receive IHS provided services.

For example, the priority (e.g., the user access level) of a user may be used to determine how to manage computing resources of IHS A (111A) to provide services to that user. As yet another example, the priority of a user may be used to identify the services that need to be provided to that user. As yet another example, the priority of a user may be used to determine how quickly communications (for the purposes of providing services in cooperation with the internal network (and its subcomponents)) are to be processed by the internal network.

Further, consider a scenario where a first user is to be treated as a normal user (e.g. a non-privileged user, a user with a user access level/tier of 4/10, a low-priority user, etc.). In such a scenario, the user level of that user may indicate that certain ports (of the subcomponents of the network corresponding to communication protocols such as the TCP, the UDP, etc.) are to be opened, other ports are to be blocked/disabled so that (i) certain services are to be provided to the user by IHS N (111N) (e.g., while the computing resources of IHS N may be capable of providing/performing any number of remote computer-implemented services, they may be limited in providing some of the services over the network enabled/provided by the network (130)) and (ii) network traffic from that user is to be afforded a normal level of quality (e.g., a normal processing rate with a limited communication bandwidth (BW)). By doing so, (i) computer-implemented services provided to the users of the clients (e.g., 110A, 110N, etc.) may be granularly configured without modifying the operation(s) of the clients and (ii) the overhead for managing the services of the clients may be reduced by not requiring modification of the operation(s) of the clients directly.

In contrast, a second user may be determined to be a high priority user (e.g., a privileged user, a user with a user access level of 9/10, a high-priority user, etc.). In such a case, the user level of that user may indicate that more ports are to be opened than were for the first user so that (i) IHS A (111A) may provide more services to the second user and (ii) network traffic from that user is to be afforded a high-level of quality (e.g., a higher processing rate than the traffic from the normal user).

As used herein, a “workload” may be a physical or logical component configured to perform certain work functions. Workloads may be instantiated and operated while consuming computing resources allocated thereto. A user may configure a data protection policy for various workload types. Examples of a workload may include (but not limited to): an AI workload, a data protection workload, a VM, a container, a network-attached storage (NAS), a database, an application, a collection of microservices, a file system (FS), small workloads with lower priority workloads (e.g., FS host data, operating system (OS) data, etc.), medium workloads with higher priority (e.g., VM with FS data, network data management protocol (NDMP) data, etc.), large workloads with critical priority (e.g., mission critical application data), etc.

As used herein, a “policy” is a collection of information, such as a backup policy or other data protection policy, that includes, for example (but not limited to): identity of source data that is to be protected, backup schedule and retention requirements for backed up source data, identity of an SLA (or a rule) that applies to source data, identity of a target device where source data is to be stored, etc.

As used herein, the term “backup” is intended to be broad in scope. In this manner, example backups (in connection with which embodiments disclosed herein) may be employed include (but not limited to): full backups, partial backups, clones, snapshots, incremental backups, differential backups, etc.

As used herein, “data retention” is a period of time, with a definite start and end, within which the data should be retained in a storage device (e.g., 101). For example, a set of user requirements and/or technical considerations (e.g., security considerations, performance considerations, etc.) of a data center may be used to generate a data retention policy specifying that user data should be retained in the database for seven years.

As used herein, a “rule” is a guideline used by an SLA component to select a particular target device (or target devices), based on the ability of the target device to meet requirements imposed by the SLA. For example, a rule may specify that an HDD having a particular performance parameter should be used as the target device. A target device selected by the SLA component may be identified as part of a backup policy or other data protection policy.

Further, while a single IHS (e.g., 111A) is considered above, the term “IHS” includes any collection of systems or sub-systems that individually or jointly execute a set, or multiple sets, of instructions to provide one or more computer-implemented services. For example, a single IHS may provide a computer-implemented service on its own (i.e., independently) while other IHSs may provide a second computer-implemented service cooperatively (e.g., each of the other IHSs may provide similar or different services that form the cooperatively provided service).

In one or more embodiments, an IHS (e.g., 111A, 111N, etc.) may implement a management model to manage the aforementioned computing resources in a particular manner. The management model may give rise to additional functionalities for the computing resources. For example, the management model may automatically store multiple copies of data in multiple locations when a single write of the data is received. By doing so, a loss of a single copy of the data may not result in a complete loss of the data. Other management models may include, for example, adding additional information to stored data to improve its ability to be recovered, methods of communicating with other devices to improve the likelihood of receiving the communications, etc. Any type and number of management models may be implemented to provide additional functionalities using the computing resources without departing from the scope of the embodiments disclosed herein.

One of ordinary skill will appreciate that an IHS (e.g., 111A, 111N, etc.) may perform other functionalities without departing from the scope of the embodiments disclosed herein. An IHS (e.g., 111A, 111N, etc.) may include/host any number of computing components/devices (e.g., Server A (112A), Server N (112N), heat exchangers, backup power supplies (e.g., 147A, 147N, FIG. 1.2), row-level or room-level power distribution units (PDUs) (e.g., 146A, 146N, FIG. 1.2), heating units, cooling units, air conditioning units, networking components/systems (e.g., 115A, 115N, FIG. 1.2), etc.). Additional details of an IHS are described below in reference to FIG. 1.2.

In one or more embodiments, an IHS (e.g., 111A, 111N, etc.) may be implemented as a computing device (e.g., 500, FIG. 5). The computing device may be, for example, a mobile phone, a tablet computer, a laptop computer, a desktop computer, a server, a distributed computing system, or a cloud resource. The computing device may include one or more processors, memory (e.g., RAM), GPUs, and persistent storage (e.g., HDDs, SSDs, etc.). The computing device may include instructions, stored in the persistent storage, that when executed by the processor(s) of the computing device cause the computing device to perform the functionality of the IHS described throughout the application.

Alternatively, in one or more embodiments, similar to a client (e.g., 110A, 110N, etc.), the IHS may also be implemented as a logical device.

Referring to FIG. 1.1A, the database (101) is demonstrated as a standalone computing device/entity; however, embodiments disclosed herein are not limited as such. The database (101) may be demonstrated as part of an IHS (e.g., 111N) (e.g., as deployed to the IHS). Further, the DTCSM (102) is demonstrated as a standalone computing device/entity; however, embodiments disclosed herein are not limited as such. The DTCSM (102) may be demonstrated as part of an IHS (e.g., 111N) (e.g., as deployed to the IHS).

Turning now to the database (101), the database (101) may provide long-term, durable, high read/write throughput data storage/protection with near-infinite scale and low-cost. The database (101) may be a fully managed cloud/remote (or local) storage (e.g., pluggable storage, object storage, block storage, file system storage, data stream storage, Web servers, unstructured storage, etc.) that acts as a shared storage/memory resource that is functional to store unstructured and/or structured data. For example, the database (101) may store data (e.g., backup data; file system metadata; assets; rules and/or procedures for performing backups of the servers; etc.). Further, the database (101) may also occupy a portion of a physical storage/memory device or, alternatively, may span across multiple physical storage/memory devices. The database (101) may include other and/or additional functionalities without departing from embodiments disclosed herein.

In one or more embodiments, the database (101) may be implemented using physical devices that provide data storage services (e.g., storing data and providing copies of previously stored data). The devices that provide data storage services may include hardware devices and/or logical devices. For example, the database (101) may include any quantity and/or combination of memory devices (i.e., volatile storage), long-term storage devices (i.e., persistent storage), other types of hardware devices that may provide short-term and/or long-term data storage services, and/or logical storage devices (e.g., virtual persistent storage/virtual volatile storage).

For example, the database (101) may include a memory device (e.g., a dual in-line memory device), in which data is stored and from which copies of previously stored data are provided. As yet another example, the database (101) may include a persistent storage device (e.g., an SSD), in which data is stored and from which copies of previously stored data is provided. As yet another example, the database (101) may include (i) a memory device in which data is stored and from which copies of previously stored data are provided and (ii) a persistent storage device that stores a copy of the data stored in the memory device (e.g., to provide a copy of the data in the event that power loss or other issues with the memory device that may impact its ability to maintain the copy of the data).

Further, the database (101) may also be implemented using logical storage. Logical storage (e.g., virtual disk) may be implemented using one or more physical storage devices whose storage resources (all, or a portion) are allocated for use using a software layer. Thus, logical storage may include both physical storage devices and an entity executing on a processor or another hardware device that allocates storage resources of the physical storage devices.

In one or more embodiments, the database (101) may store/log/record unstructured and/or structured data that may include (or specify), for example (but not limited to): a backup policy/practice; telemetry data including past and present device usage of one or more computing devices; data for execution of applications/services including server applications and associated end-points; corpuses of annotated data used to build/generate and train processing classifiers for trained ML/AI models; linear, non-linear, and/or AI model parameters; data tags; an identifier of a sensor; a product identifier of a client (e.g., 110A); a type of a client; historical sensor data/input (e.g., visual sensor data, audio sensor data, electromagnetic radiation sensor data, temperature sensor data, humidity sensor data, corrosion sensor data, etc., in the form of text, audio, video, touch, and/or motion) and its corresponding details; an identifier of a data item; a size of the data item; an identifier of a user (e.g., a unique string or combination of bits associated with a particular user) who initiated a backup (via a client); a distributed model identifier that uniquely identifies a distributed model; a user activity performed on a data item; a cumulative history of user/administrator activity records obtained over a prolonged period of time; a setting (and a version) of a mission critical application/workload executing on a server (e.g., 112A); configuration information associated with a server (e.g., 112A); a job detail of a job that has been initiated by a server (e.g., 112A); a type of the job (e.g., a non-parallel processing job, a parallel processing job, an analytics job, etc.); information associated with a hardware resource set (discussed below) of a server (e.g., 112A); a completion timestamp encoding a date and/or time reflective of the successful completion of a job/workload; a time duration reflecting the length of time expended for executing and completing a job; a backup retention period associated with an asset (e.g., data item); a status of a job (e.g., how many jobs are still active, how many jobs are completed, etc.); a number of requests handled (in parallel) per minute (or per second, per hour, etc.) by a server (e.g., 112A); a number of errors encountered when handling a job (e.g., a backup process); a documentation that shows how a server (e.g., 112A) performs against an SLO and/or an SLA; a set of requests received by a server (e.g., 112A); a set of responses provided (by the server) to those requests; information regarding an administrator (e.g., a high-priority trusted administrator, a low-priority trusted administrator, etc.) related to a job; tier/level information of a user (e.g., a high-priority user, a low-priority user, etc.); a geographic location (e.g., a country) associated with the user; a timestamp showing when a specific request is processed by a server (e.g., 112A); computing resource details (including details of hardware components and/or software components) and an IP address of a server (e.g., 112A) hosting an application where a specific request is processed; information with respect to historical metadata (e.g., system logs, applications logs, telemetry data including past and present device usage of one or more computing devices in the system (100), etc.); computing resource details and an IP address of a client that sent a specific request (e.g., to a server); an existing knowledge base (KB) article; a technical support history documentation of a customer/user; a port's user guide; a port's release note; a community forum question and its associated answer; a catalog file of an application upgrade; details of a compatible OS version for an application upgrade to be installed; an application upgrade sequence; a solution or a workaround document for a software failure; one or more lists that specify which computer-implemented services should be provided to which user (depending on a user access level of a user); a fraud report for an invalid user; a set of SLAs (e.g., an agreement that indicates a period of time required to retain a profile of a user); information with respect to a user/customer experience; checkpoint data; data used for AI model training and/or AI inferencing; a record that is associated with a digital twin of a workload; a record that is associated with a digital twin of a server; a record that is associated with a digital twin of an IHS; historical data associated with one or more workloads; etc.

In one or more embodiments, information associated with a hardware resource set (e.g., including at least resource related parameters) may specify, for example (but not limited to): a configurable CPU option (e.g., a valid/legitimate vCPU count for a server (e.g., 112A)), a configurable network resource option (e.g., enabling/disabling single-root input/output virtualization (SR-IOV) for the server), a configurable memory option (e.g., maximum and minimum memory for the server), a configurable GPU option (e.g., allowable scheduling policy and/or virtual GPU (vGPU) count combinations for the server), a configurable DPU option (e.g., legitimacy of disabling inter-integrated circuit (I2C) for the server), a configurable storage space option (e.g., a list of disk cloning technologies across one or more servers in the system (100)), a configurable storage I/O option (e.g., a list of possible file system block sizes across all target file systems), a user type (e.g., a knowledge worker, a task worker with relatively low-end compute requirements, a high-end user that requires a rich multimedia experience, etc.), a network resource related template (e.g., a 10 GB/s BW with 20 ms latency quality of service (QoS) template), a DPU related template (e.g., a 1 GB/s BW vDPU with 1 GB vDPU frame buffer template), a GPU related template (e.g., a depth-first vGPU with 1 GB vGPU frame buffer template), a storage space related template (e.g., a 40 GB SSD storage template), a CPU related template (e.g., a 1 vCPU with 4 cores template), a memory resource related template (e.g., an 8 GB DRAM template), a vCPU count per analytics engine, a virtual NIC (vNIC) count per server in the system (100), a wake on LAN support configuration (e.g., supported/enabled, not supported/disabled, etc.), a vGPU count per server in the system (100), a type of a vGPU scheduling policy (e.g., a “fixed share” vGPU scheduling policy), a storage mode configuration (e.g., an enabled high-performance storage array mode), etc.

While the database (101) has been illustrated and described as including a limited number and type of data, the database (101) may store additional, less, and/or different data without departing from the scope of the embodiments disclosed herein. One of ordinary skill will appreciate that the database (101) may perform other functionalities without departing from the scope of the embodiments disclosed herein.

Referring to FIG. 1.1A, the system (100) further includes the DTCSM (102). The DTCSM (102) may include functionality for generating, storing, updating, providing, using, and/or otherwise managing a set/library of digital twins that each correspond to an entity/component (e.g., a hardware component (or a hardware computing resource) digital twin, a workload digital twin, a server digital twin, an IHS digital twin, etc.). Any other entity may be described using a digital twin without departing from the scope of the embodiments disclosed herein. Additional details of the DTCSM are described below in reference to FIG. 1.3.

In one or more embodiments, the DTCSM (102) may be implemented as a computing device (e.g., 500, FIG. 5). The computing device may be, for example, a mobile phone, a tablet computer, a laptop computer, a desktop computer, a server, a distributed computing system, or a cloud resource. The computing device may include one or more processors, memory (e.g., RAM), GPUs, and persistent storage (e.g., HDDs, SSDs, etc.). The computing device may include instructions, stored in the persistent storage, that when executed by the processor(s) of the computing device cause the computing device to perform the functionality of the DTCSM described throughout the application.

Alternatively, in one or more embodiments, similar to a client (e.g., 110A, 110N, etc.), the DTCSM may also be implemented as a logical device.

In one or more embodiments, depending on their geographic location in the world, any computing device (e.g., Server A (112A)) of an IHS (e.g., 111A), the clients (e.g., 110A, 110N, etc.), the database (101), and the DTCSM (102) may be powered by a power grid (e.g., 120A, 120B, etc.). For example, (a) the power grid (120A) and IHS A (111A) may be located in a first geographic location (e.g., Houston, TX) in the world, (b) the power grid (120B) and IHS N (111N) may be located in a second geographic location (e.g., Lyon, France) in the world, and (c) the power grid (120A) may provide electricity to, at least, the clients (e.g., 110A, 110B, etc.) and IHS A (111A). A power grid (e.g., 120A, 120B, etc.) may be an extensive cross-country network that includes sources of power used to enable electricity distribution to the aforementioned components (to enable, at least, each component's operations).

As indicated above, a power grid (e.g., 120A, 120B, etc.) may emit energy/electricity to the aforementioned components/computing devices and may include (or connected to) one or more power generating/generation sources/generators (e.g., power plants (e.g., nuclear power plants, natural gas power plants, coal-fired power plants, hydropower plants, etc.), dams, solar farms, wind farms, etc.). A power grid (e.g., 120A, 120B, etc.) may include a system of interconnected entities that generate, transmit, and distribute power to the aforementioned components. A power grid (e.g., 120A, 120B, etc.) may include an infrastructure that connects the power sources to the aforementioned components.

In one or more embodiments, the generation of power by a power grid (e.g., 120A, 120B, etc.) to provide electricity to the aforementioned components/computing devices may result in grid emissions (e.g., average emissions). Grid emissions may refer to an environmental impact that results in the production of power for use by the components/computing devices of the system (100). The environmental impact includes the emission of greenhouse gases, such as carbon dioxide, by power generating sources. Each of the aforementioned power generating sources may correspond to a level of grid emission based on the amount of greenhouse gases emitted due to the generation of power. For example, a coal-fired power plant may correspond to a higher level of grid emissions than a hydropower plant or a wind farm.

In one or more embodiments, grid emissions caused by a given workload may be calculated (or otherwise measured) based on the amount of computing resources used to execute the workload, an amount of electricity used to power the said amount of computing resources, and a power supply profile (e.g., a type of power plant(s)) of a power grid (e.g., 120A, 120B, etc.) used to supply the said amount of electricity. Such calculated (or otherwise measured) grid emissions may be stored in a corresponding workload report (e.g., workload information, see FIG. 1.2) of the given workload.

In one or more embodiments, as being a logical entity (e.g., autonomous software program), an AI agent of the AI agents (109) may interact with its environment, collect data, and reason, to reach a predetermined goal, with minimal user/human interaction. In one or more embodiments, an AI agent of the AI agents (109) may employ large language models (LLMs) to process and generate information in a multi-modal fashion with multiple data types (e.g., structured data, semi-structured data, unstructured data, etc.). An AI agent (e.g., a reactive AI agent, a proactive AI agent, a hybrid AI agent, etc.) of the AI agents (109) may possess memory to recall past interactions in each context, enabling the agent to learn from events. Further, an AI agent's access to context-specific tools and application programming interfaces (APIs) may extend the AI agent's capabilities in a certain area, allowing the AI agent to perform a greater level of complexity of various tasks. For example, an AI agent of the AI agents (109) may: (i) send a workload execution request to a WIE (e.g., 104, FIG. 1.2), (ii) infer whether a server (e.g., 112A) is decommissioned and can be recommissioned to another IHS, (iii) based on (ii), notify a user about the availability of a decommissioned server, (iv) be generated by a specific component (e.g., 105, FIG. 1.2) of an IHS (so that the specific component can query other IHSs to infer whether there are alternative IHSs to the local IHS), and (v) act as the IIWS (190) and perform functionalities of the IIWS.

One of ordinary skill will appreciate that an AI agent of the AI agents (109) may perform other functionalities without departing from the scope of the embodiments disclosed herein.

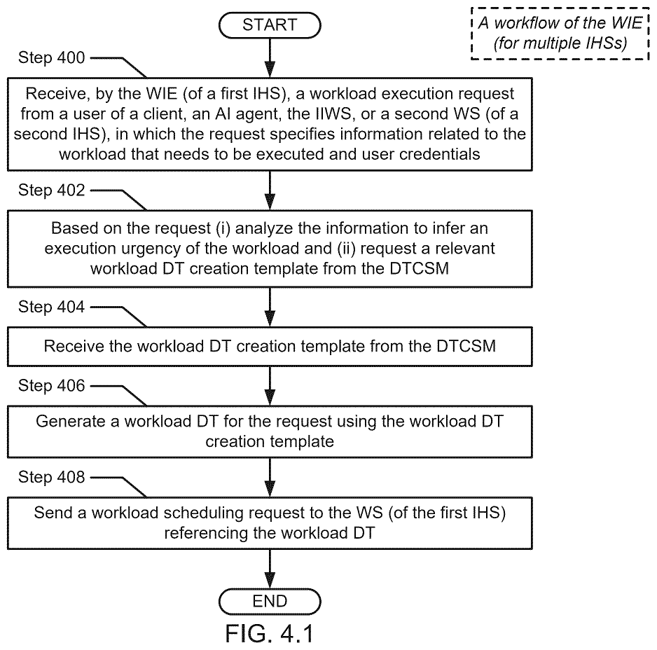

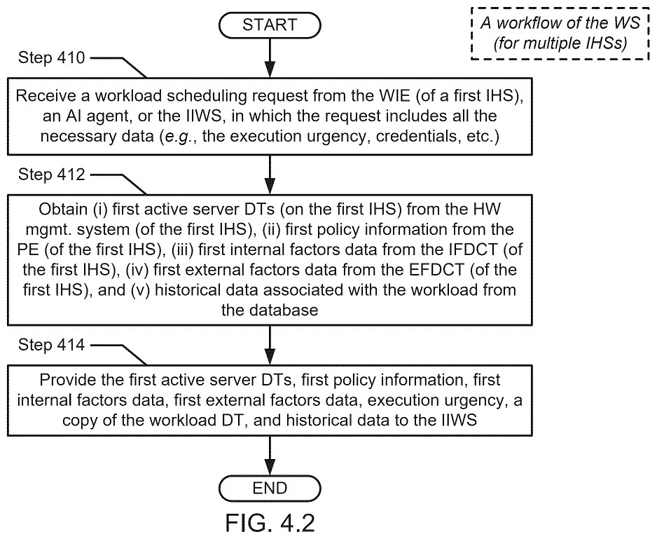

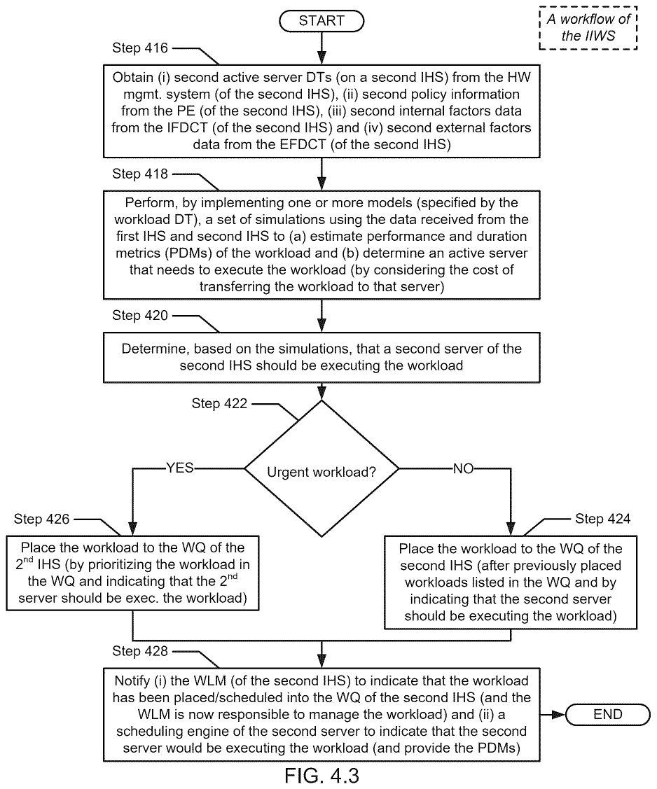

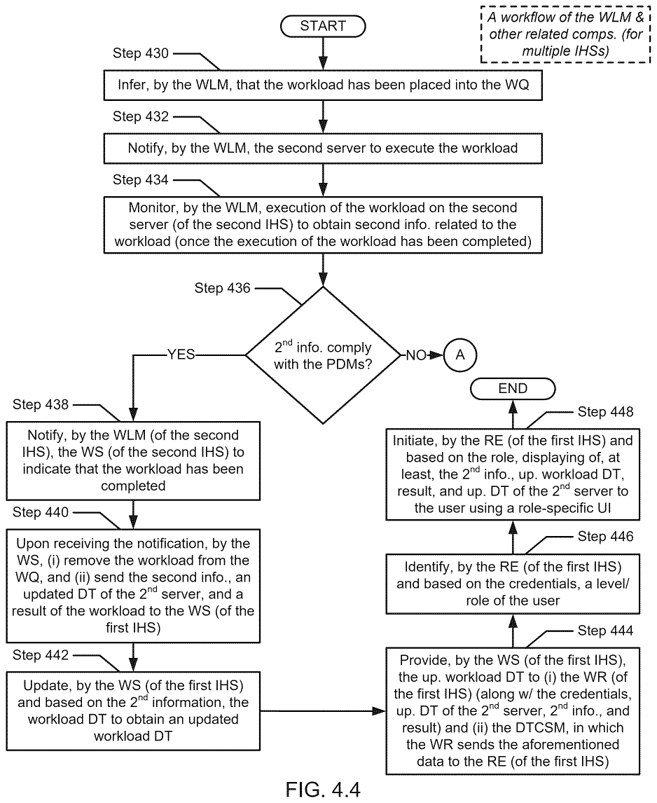

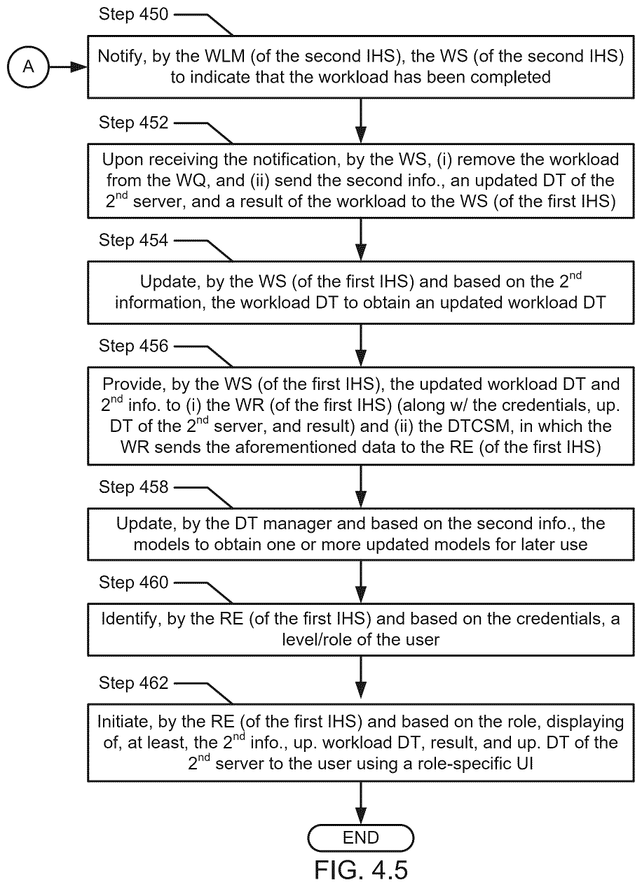

In one or more embodiments, as being a physical computing device or a logical computing device, the IIWS (190) may include functionality to: (i) identify potential alternative locations (e.g., IHSs) to shift a workload for execution (e.g., location-shifting) and (ii) configured to perform all, or a portion, of the functionalities described in FIG. 4.3. One of ordinary skill will appreciate that the IIWS (190) may perform other functionalities without departing from the scope of the embodiments disclosed herein. The IIWS (190) may be implemented as a computing device using hardware (e.g., any number of integrated circuits for processing computer readable instructions), software (e.g., a computer program), or any combination thereof.

In one or more embodiments, all, or a portion, of the components of the system (100) may be operably connected each other and/or other entities via any combination of wired and/or wireless connections. For example, the aforementioned components may be operably connected, at least in part, via the network (130). Further, all, or a portion, of the components of the system (100) may interact with one another using any combination of wired and/or wireless communication protocols.

In one or more embodiments, the network (130) may represent a (decentralized or distributed) computing network and/or fabric configured for computing resource and/or messages exchange among registered computing devices (e.g., the clients, the IHSs, etc.). As discussed above, components of the system (100) may operatively connect to one another through the network (e.g., a storage area network (SAN), a personal area network (PAN), a LAN, a metropolitan area network (MAN), a WAN, a mobile network, a wireless LAN (WLAN), a virtual private network (VPN), an intranet, the Internet, etc.), which facilitates the communication of signals, data, and/or messages. In one or more embodiments, the network (130) may be implemented using any combination of wired and/or wireless network topologies, and the network may be operably connected to the Internet or other networks. Further, the network (130) may enable interactions between, for example, the clients and the IHSs through any number and type of wired and/or wireless network protocols (e.g., TCP, UDP, IPv4, etc.).

The network (130) may encompass various interconnected, network-enabled subcomponents (not shown) (e.g., switches, routers, gateways, cables etc.) that may facilitate communications between the components of the system (100). In one or more embodiments, the network-enabled subcomponents may be capable of: (i) performing one or more communication schemes (e.g., IP communications, Ethernet communications, etc.), (ii) being configured by one or more components in the network, and (iii) limiting communication(s) on a granular level (e.g., on a per-port level, on a per-sending device level, etc.). The network (130) and its subcomponents may be implemented using hardware, software, or any combination thereof.

In one or more embodiments, before communicating data over the network (130), the data may first be broken into smaller batches (e.g., data packets) so that larger size data can be communicated efficiently. For this reason, the network-enabled subcomponents may break data into data packets. The network-enabled subcomponents may then route each data packet in the network (130) to distribute network traffic uniformly.

In one or more embodiments, the network-enabled subcomponents may decide how real-time (e.g., on the order of ms or less) network traffic and non-real-time network traffic should be managed in the network (130). In one or more embodiments, the real-time network traffic may be high-priority (e.g., urgent, immediate, etc.) network traffic. For this reason, data packets of the real-time network traffic may need to be prioritized in the network (130). The real-time network traffic may include data packets related to, for example (but not limited to): videoconferencing, web browsing, voice over Internet Protocol (VoIP), etc.

While FIG. 1.1A shows a configuration of components, other system configurations may be used without departing from the scope of the embodiments disclosed herein.

Turning now to FIG. 1.1B, FIG. 1.1B shows a diagram of a system (that includes a single IHS) in accordance with one or more embodiments disclosed herein. The components shown in FIG. 1.1B may have the same or substantially the same functionalities as the like components in FIG. 1.1A.

While FIG. 1.1B shows a configuration of components, other system configurations may be used without departing from the scope of the embodiments disclosed herein.

Turning now to FIG. 1.2, FIG. 1.2 shows a diagram of an IHS (e.g., IHS A (111A)) in accordance with one or more embodiments disclosed herein. More specifically, FIG. 1.2 shows additional details of an IHS (e.g., a small data center in a factory, a cloud device, a manufacturing execution subsystem, etc.) in accordance with one or more embodiments disclosed herein. As being a physical computing device, IHS A (111A) may include a rack (not shown), a set of servers (e.g., 112A, 112N, etc.), a set of network systems (e.g., 115A, 115N, etc.), a workload orchestration system (WOS) (103), a set of storage systems (e.g., 145A, 145N, etc.), a set of backup power supplies (e.g., 147A, 147N, etc.), a set of PDUs (e.g., 146A, 146N, etc.), a cluster/IHS management system (116), a set of data collectors (e.g., 121, 122, etc.), a policy engine (120), and a report engine (117). IHS A (111A) may include additional, fewer, and/or different components without departing from the scope of the embodiments disclosed herein. Each component may be operably connected to any of the other components via any combination of wired and/or wireless connections. Each component illustrated in FIG. 1.2 is discussed below.

In one or more embodiments, the rack may be a chassis (e.g., a mechanical structure) that is configured to house/host one or more computing devices (or blades) (e.g., 112A, 112N, 115A, 145A, 146A, 147A, etc.) and their components, to be positioned with respect to one another. For example, the rack may be a mountable enclosure that enables the computing devices to be disposed within the rack. The rack may be implemented as other types of structures adapted to host, position, orient, and/or otherwise physically, mechanically, electrically, and/or thermally manage the computing devices. By managing the computing devices, the rack may enable the computing devices to be densely packed in a space without negatively impacting the operation of IHS A (111A).

In one or more embodiments, as being a physical computing device, a server (e.g., 112A, 112N, etc.) may be a mechanical structure for housing hardware components (or hardware computing resources). For example, the server (e.g., 112A, 112N, etc.) may be implemented as a rack mountable enclosure for housing hardware components. The server (e.g., 112A, 112N, etc.) may be adapted to be disposed within the rack, and/or utilize services provided by the rack and/or other components available in the system (e.g., 100, FIG. 1.1A).

In one or more embodiments, the server (e.g., 112A, 112N, etc.) may have any instrumentality or aggregate of instrumentalities (e.g., a hardware layer (113), a software layer (114), etc.) operable to compute, classify, process, transmit, receive, retrieve, originate, switch, store, display, manifest, detect, record, reproduce, handle, and/or utilize any form of data for business, management, entertainment, or other purposes. The server (e.g., 112A, 112N, etc.) may provide any quantity and any type of computer-implemented services, for example, to users of a client (e.g., 110A, FIG. 1.1A). To provide computer-implemented services, the server (e.g., 112A, 112N, etc.) may be a heterogeneous set, including a collection of physical “computing” components/resources (e.g., 113) configured to perform operations of the server and/or otherwise execute a collection of logical “computing” components/resources (e.g., 114) of the server. As used herein, a computing resource may be a measurable quantity of a compute-relevant resource type that may be requested, allocated, and/or consumed.

In one or more embodiments, the hardware layer (113) may represent the collection of physical hardware components/resources (e.g., a hardware resource set, see FIG. 1.1A), and the software layer (114) may represent the collection of logical “computing” components (e.g., applications (and/or content accessible through applications), virtualization resources (see FIG. 1.1A), etc.). A physical hardware component of the hardware layer (113) may be (or may be implemented as), for example (but not limited to): a processing resource (e.g., CPU, a GPU, a tensor processing unit (TPU), a neural processing unit (NPU), etc., see FIG. 1.1), a networking resource (e.g., a NIC, a peripheral interface express (PCIe) device, etc., see FIG. 1.1A), a storage/memory resource (e.g., an SSD, an HDD, Flash memory, etc., see FIG. 1.1A), a memory management unit (MMU), etc.

In one or more embodiments, the server (e.g., 112A, 112N, etc.) may include functionality to execute one or more workloads (e.g., AI (or AI model) training workloads, AI inferencing workloads, etc.) using the hardware layer (113) and/or the software layer (114). For example, the server may include a local AI application (not shown) that manages the execution of various AI workloads on the hardware layer. In one or more embodiments, the server (e.g., 112A, 112N, etc.) may be operatively connected to another server (e.g., to transmit data, to receive data, etc.) via a top-of-rack (ToR) switch when the servers are in the same server rack, or via a scale-out network (e.g., 130, FIG. 1.1A) when the servers are in different server racks and/or in different geographic locations/zones across the world.

The server (e.g., 112A, 112N, etc.) may include additional, fewer, and/or different components without departing from the scope of the embodiments disclosed herein. One of ordinary skill will appreciate that the server (e.g., 112A, 112N, etc.) may perform other functionalities without departing from the scope of the embodiments disclosed herein.

In one or more embodiments, as being a physical computing device, a network system/device (e.g., 115A, 115N, etc.) may facilitate inter-server communications for servers (e.g., 112A, 112N, etc.) within the rack as well as communications between the servers and external components (e.g., other servers in other server racks, the network (e.g., 130, FIG. 1.1A), etc.). One of ordinary skill will appreciate that the network (or networking) system (e.g., 115A, 115N, etc.) may perform other functionalities without departing from the scope of the embodiments disclosed herein. The network system (e.g., a ToR switch) may be implemented as a computing device using hardware (e.g., any number of integrated circuits for processing computer readable instructions), software (e.g., a computer program), or any combination thereof.

In one or more embodiments, a storage system (e.g., 145A, 145N, etc.) may include additional, less, and/or different functionalities (and/or components) from a storage/memory resource (discussed above in reference to FIG. 1.1A) without departing from the scope of the embodiments disclosed herein. One of ordinary skill will appreciate that the storage system (e.g., 145A, 145N, etc.) may perform other functionalities without departing from the scope of the embodiments disclosed herein. The storage system (e.g., 145A, 145N, etc.) may be implemented as a computing device using hardware (e.g., any number of integrated circuits for processing computer readable instructions), software (e.g., a computer program), or any combination thereof.

In one or more embodiments, a backup power supply (e.g., 147A, 147N, etc.) can be used as a dispatchable power source to provide power to a power grid (e.g., 120A, FIG. 1.1A) when necessary. A backup power supply/source (e.g., 147A, 147N, etc.) may be any source of power, for example (but not limited to): an uninterruptible power supply (UPS) unit, an internal-combustion power generator (e.g., a diesel-powered generator, a hydrogen-powered generator, etc.), a fuel cell, a solar panel, a battery, etc. Further, when necessary, a backup power supply (e.g., 147A, 147N, etc.) may provide direct current (DC) power to the components of IHS A (111A) and may convert alternating current (AC) power (obtained from a centralized power station) to DC power.

In one or more embodiments, a backup power supply (e.g., 147A, 147N, etc.) may provide “N” or “2×N” power supply resiliency to IHS A (111A). For example, if IHS A (111A) has “2×N” power supply resiliency, this means that the backup power supply has a functionality to provide twice the amount of power needed for IHS A (111A). In one or more embodiments, the backup power supply may provide a high-level power supply resiliency to IHS A (111A), ensuring that IHS A (111A) has no downtime, for example, while performing a service maintenance or experiencing a failure.

One of ordinary skill will appreciate that the backup power supply (e.g., 147A, 147N, etc.) may perform other functionalities without departing from the scope of the embodiments disclosed herein.

As discussed above, IHS A (111A) may host a set of PDUs (e.g., 146A, 146N, etc.). In one or more embodiments, a “PDU” may be a component with multiple outlets designed to distribute (e.g., to transfer) power from a power source to components disposed within the rack of IHS (111A). To compare, for example, a backup power supply (e.g., 147A) may provide battery backup to a network system (e.g., 115A) during power outages. A backup power supply (e.g., 147A) may also filter incoming power to the network system and provides a surge protection. However, a PDU (e.g., 146A) may distribute power from a power source to the network system, which means the PDU may not generate or condition power on its own. The aforementioned example is not intended to limit the scope of the embodiments disclosed herein.

To distribute power and/or to enhance remote power management in various structural conditions, a PDU (e.g., 146A) may be manufactured in a variety of styles, for example (but not limited to): a local metered PDU, a monitored PDU, a switchable PDU, a hot-swap PDU, a network switch added PDU, etc. In one or more embodiments, the various structural conditions may include, for example (but not limited to): a type of a rack, a required input power to feed a component within a rack, a plug type of a component, etc.

In many cases, the rack (of IHS A (111A)) may be configured with multiple PDUs (e.g., 146A, 146N, etc.) for various reasons, for example (but not limited to): power redundancy, power sharing, power cable management, etc.

One of ordinary skill will appreciate that the PDU (e.g., 147A, 147N, etc.) may perform other functionalities without departing from the scope of the embodiments disclosed herein.

In one or more embodiments, as being a physical computing device or a logical computing device, the policy engine (120) may be configured to communicate with the report engine (117) (for example, to manage one or more policies/rules (e.g., reducing carbon emissions of IHS A (111A), reducing the cost of managing IHS A (111A), etc.) defined by an administrator of IHS A (111A) using a UI (e.g., 118A)). One of ordinary skill will appreciate that the policy engine (120) may perform other functionalities without departing from the scope of the embodiments disclosed herein. The policy engine (120) may be implemented as a computing device using hardware (e.g., any number of integrated circuits for processing computer readable instructions), software (e.g., a computer program), or any combination thereof.

In one or more embodiments, the cluster management system (116) may include/host a hardware management system (140) and a DT of IHS A (195). In one or more embodiments, the hardware management system (140) may include an IHS scheduler (141), an IHS queue (142), a set of active IHS DTs (143), and an IHS reporter (144), in which the hardware management system (140) may operate in parallel with the WOS (103). The hardware management system (140) may include additional, fewer, and/or different components without departing from the scope of the embodiments disclosed herein.

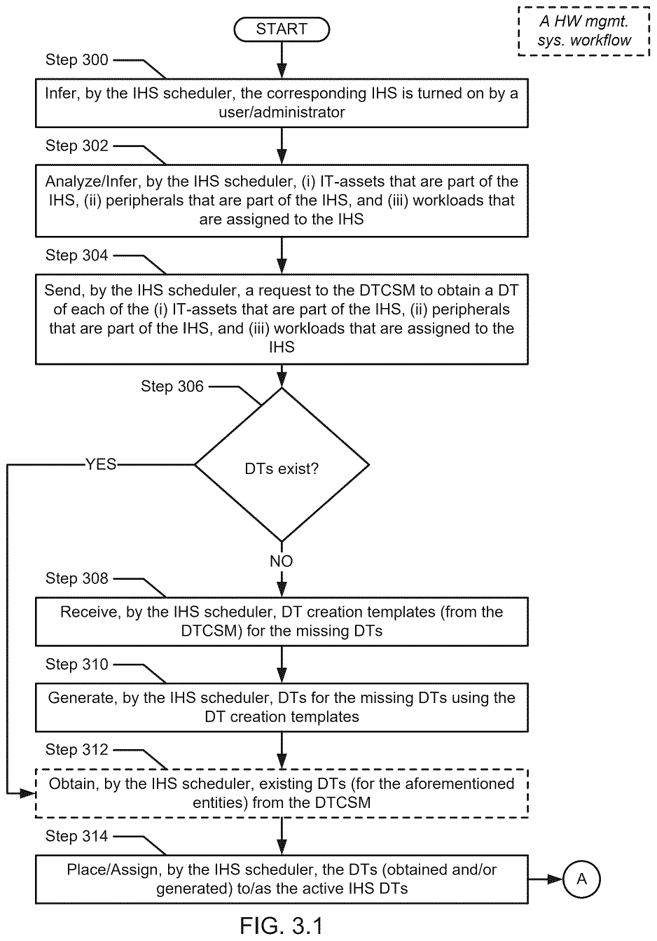

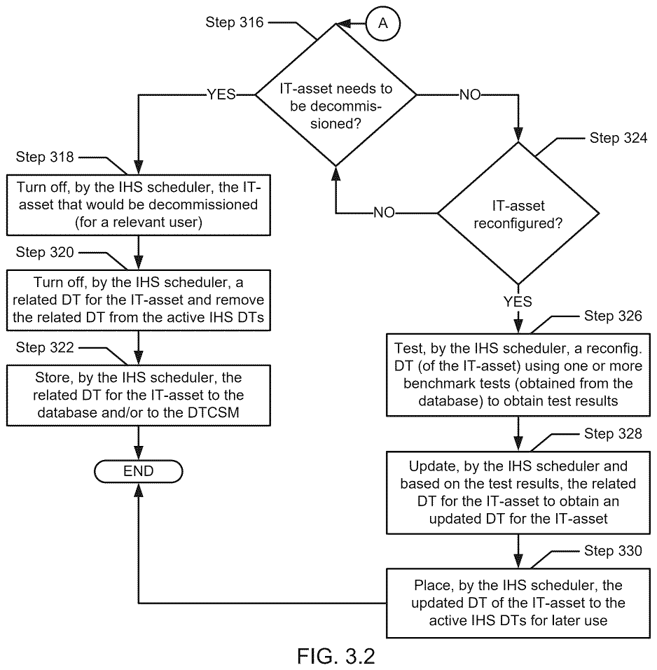

In one or more embodiments, as being a physical computing device or a logical computing device, the IHS scheduler (141) may include functionality to: (i) analyze each hardware component/system and software component of IHS A (111A) and one or more workloads assigned to IHS A (111A); (ii) based on (i), place a DT of each active component (e.g., a component that is being used) to the active IHS DTs (143) and place a DT of each active or non-active component to the IHS DTs (195); (iii) based on (i), keep the IHS queue (142) up-to-date (in order to, for example, indicate which workloads are being executed on IHS A (111A), which servers (e.g., 112A, 112N, etc.) are assigned to which workloads (along with servers of other IHSs), the availability of IHS A (111A), the health status of IHS A (111A), etc.); (iv) keep a DT of each active or non-active component up-to-date; (v) using the IHS reporter (144), analyze and report/send metrics (e.g., performance metrics, energy usage metrics, etc.) of each component of IHS A (111A) to the report engine (117); (vi) based on the metrics, update (or fine-tune) a system ML model (that is used to analyze the metrics) to obtain an updated system ML model; and/or (vii) perform all, or a portion, of the functionalities described in FIG. 3.1-3.2.

One of ordinary skill will appreciate that the IHS scheduler (141) may perform other functionalities without departing from the scope of the embodiments disclosed herein. The IHS scheduler (141) may be implemented as a computing device using hardware (e.g., any number of integrated circuits for processing computer readable instructions), software (e.g., a computer program), or any combination thereof.

In one or more embodiments, the WOS (103) may host/include a WIE (104), a WS (105), a workload queue (WQ) (106), a set of active workload DTs (107), a workload reporter (WR) (108), and a WLM (194). The WOS (103) may include additional, fewer, and/or different components without departing from the scope of the embodiments disclosed herein.

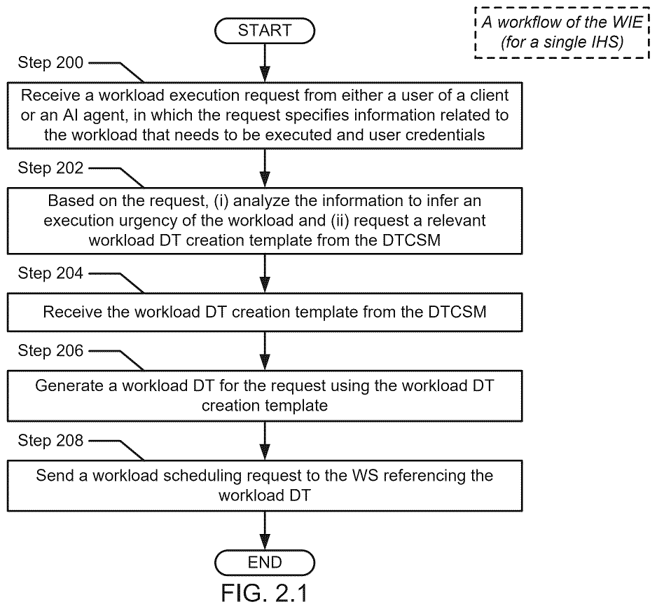

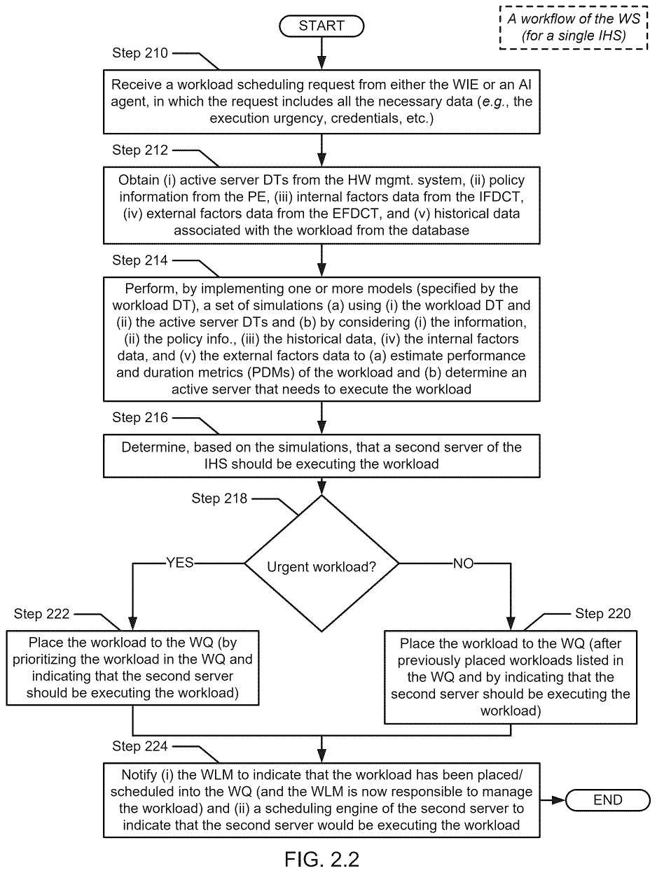

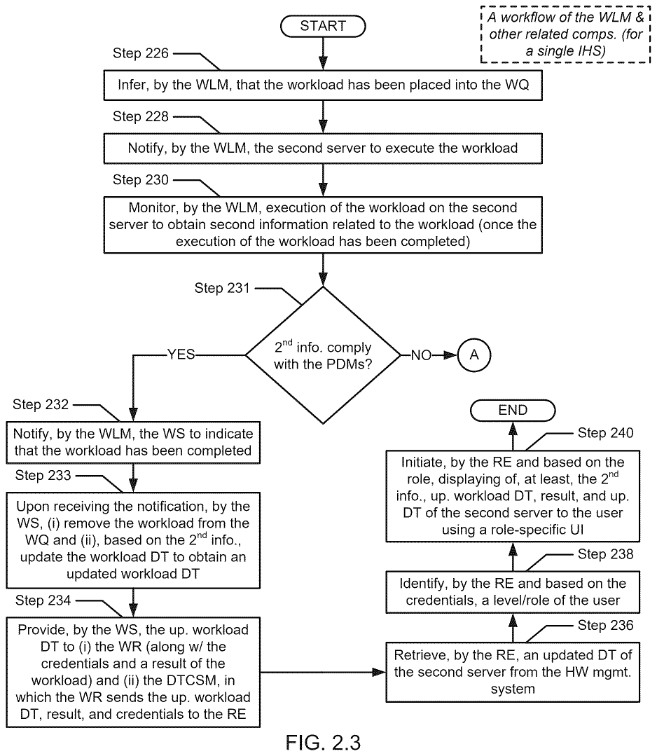

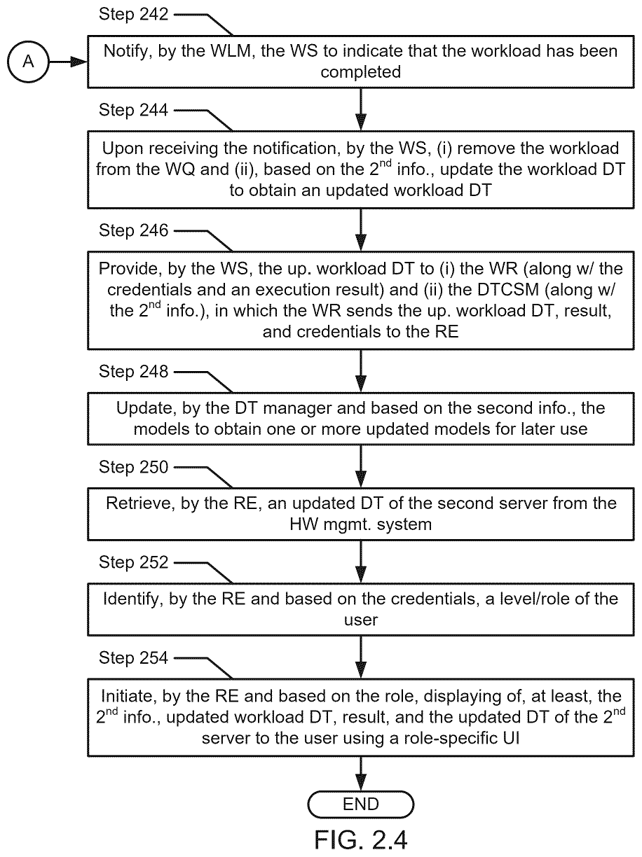

In one or more embodiments, as being a physical computing device or a logical computing device, the WIE (104) may include functionality to: (i) communicate directly with the DTCSM (e.g., 102, FIG. 1.1A) to instruct the DTCSM for receiving a set of workload DT creation templates to generate a set of active workload DTs (107) for workloads (that needs to be executed) and (ii) perform all, or a portion, of the functionalities described in FIG. 2.1. One of ordinary skill will appreciate that the WIE (104) may perform other functionalities without departing from the scope of the embodiments disclosed herein. The WIE (104) may be implemented as a computing device using hardware (e.g., any number of integrated circuits for processing computer readable instructions), software (e.g., a computer program), or any combination thereof.

In one or more embodiments, as being a physical computing device or a logical computing device, the WS (105) may include functionality to: (i) obtain/retrieve real-time (or near-real-time) internal factors data and external factors data (including, at least, environmental conditions) from corresponding entities (e.g., an internal factors data collector and tracker (IFDCT) (121) and an external factors data collector and tracker (EFDCT) (122), respectively), and use the aforementioned data to make more informed decisions for workload scheduling/deployment to the WQ (106); (ii) manage one or more workloads (that are received from one or more users) in terms of scheduling/deployment (e.g., manage multiple workloads by queuing, comparing, and prioritizing based on the internal factors data, external factors data, required time to complete a related workload, and estimates of workload runtime requirements, and make informed decisions to schedule each workload accordingly); (iii) perform an optimized scheduling of a workload by employing a model (e.g., an optimizer ML model) and leveraging historical processing times of the workload (or a similar workload) to estimate execution duration of the workload (so that the workload can be executed efficiently and timely while minimizing carbon emissions due to execution of the workload); (iv) reduce total energy required to execute a workload by considering real-time internal factors data (e.g., IHS power distribution losses, cooling system energy requirements, etc.) so that, for example, non-urgent/critical workloads can be scheduled (or rescheduled) to a corresponding server when the cooling system overhead of a related IHS is significantly lower than average; (v) by considering real-time external factors data, schedule a workload when grid emissions (e.g., average grid emissions) indicate a significant use of renewable resources (e.g., solar farm, wind farm, etc.) (said another way, when energy demand to execute the workload can be met with lower emission power generators) to minimize carbon emissions associated with the workload; (vi) by considering real-time external factors data (e.g., current grid information on a national or global basis), schedule a workload to a server that is located in a region in the world supporting lower carbon emissions; (vii) based on (v)-(vi) and in conjunction by the IIWS (e.g., 190, FIG. 1.1A) (or solely by the IIWS), reduce executional costs of a workload and minimize carbon emissions of the workload by shifting the workload to a server that is hosted in an edge device (e.g., an IHS that is located in the functional edge region), an edge node (e.g., an IHS that is located in the far edge region), or another edge node (e.g., an IHS that is located in the near edge region); and/or (viii) use a DT of a workload in order to capture (and store) important workload input, output, and performance characteristics related to the workload (and, using the WR (108), provide those characteristics to the report engine (117)).

One of ordinary skill will appreciate that the WS (105) may perform other functionalities without departing from the scope of the embodiments disclosed herein. The WS (105) may be implemented as a computing device using hardware (e.g., any number of integrated circuits for processing computer readable instructions), software (e.g., a computer program), or any combination thereof. In one or more embodiments, the WS (105) may be configured to perform all, or a portion, of the functionalities described in FIG. 2.2-2.4, 4.2, and 4.4-4.5.

In one or more embodiments, the WS (105) may re-run on a regular basis (at the background) to ensure that the WQ (106) properly represents current priorities of workloads (for example, based on user-defined policies and/or IHS administrator-defined policies, or if a newer workload has been added to the WQ). More specifically, the WS (105) may be actively responding to a change in internal factors data, external factors data, or an external request that drives a re-analysis and potential re-shuffling of the WQ (106).

For example, a user of a client (e.g., 110A, FIG. 1.1A) or an AI agent (e.g., 109, FIG. 1.1A) may want to change characteristics (e.g., input files or parameters, the priority, etc.) of a workload while the workload is pending in the WQ (106), which may be requested directly from the WQ (i.e., the user views the WQ, via a related UI (e.g., 118A), and decides to make changes in the WQ). As yet another example, re-analysis and potential re-shuffling of the WQ (106) may include a wait state when the WS (105) is idle until the WS either receives a new workload scheduling request or data that may drive a change in the WQ.

Further, the WS (105) may need to handle requests from the IIWS (e.g., 190, FIG. 1.1A) or a second WS (of another IHS) on a contingency basis. For example, the WS (105) may place a workload into the WQ (106), but flags the workload as contingent on a future signal from the WS (105) (by sending a signal to the WLM (194)). As yet another example, handling requests from the IIWS or a second WS may be necessary if the IIWS or the second WS needs to temporarily lock down computing resources while the IIWS or the second WS assesses options across multiple IHSs. Then, once the IIWS or the second WS makes a decision, the IIWS or the second WS signals the WS (105) to remove (i) the contingency on the workload in the WQ or (ii) the workload from the WQ.

In one or more embodiments, as being a physical computing device or a logical computing device, the WLM (194) may include functionality to: (i) manage the lifecycle of a workload (including an active DT of the workload); (ii) after deployment of workload, monitor execution of the workload on a related server to obtain information (e.g., a workload report, see Step 230 of FIG. 2.3) associated with the workload from the server; (iii) make sure that the DT of the workload is in sync with the workload; and/or (iv) configured to perform all, or a portion, of the functionalities described in FIG. 2.3-2.4 and 4.4-4.5.

In one or more embodiments, information associated with the workload may include, for example (but not limited to): computing resource information (associated with a server that has been assigned to execute the workload), external factors data (e.g., power grid intensity information) associated with the server, computing resource utilization information (indicating which computing resources of the server have been utilized to execute the workload), etc.

In one or more embodiments, computing resource information may include/specify data about the computing resources/components (of the server) involved in the execution of the workload. For example, computing resource information may include an identifier of each computing resource/device (of a server) that is used for to execute the workload and a type of each computing device.

Further, computing resource utilization information may be a combination of time series that each correspond to the utilization of one of the computing resources (of the server, such as processing resources, storage/memory resources, networking resources, etc.) while executing the workload.

In one or more embodiments, power grid intensity information may include information calculated, or measured, about the grid emissions (e.g., average grid emissions) caused by powering the computing resources (of the server) used to execute the workload. Power grid intensity information may be calculated by the WS (105) discussed above during monitoring execution of the workload. For example, power grid intensity information may be calculated by identifying a power resource used to power the computing resources, identifying a profile of the power resource (e.g., a type of power plant used to generate electricity), and measuring an amount of energy used to power/support the computing component utilization. Other mechanisms may be used to calculate (or measure) the power grid intensity information without departing from the scope of the embodiments disclosed herein.

One of ordinary skill will appreciate that the WLM (194) may perform other functionalities without departing from the scope of the embodiments disclosed herein. The WLM (194) may be implemented as a computing device using hardware (e.g., any number of integrated circuits for processing computer readable instructions), software (e.g., a computer program), or any combination thereof.

In one or more embodiments, as being a physical computing device or a logical computing device, the report engine (117) may include functionality to, at least: (i) generate and provide a portal/visualizer (e.g., a UI, a GUI, an API), a human-machine interface, a communication channel, an AI-based dashboard, etc.), which contextualizes information for a specific user (the manager may initially present information/metrics (on a UI) related to his/her role/level, but over time and based on previous user interactions, may tailor the metrics (using a RAG engine (119)) that better align with the user's/stakeholder's areas of interest (so that the same information can be presented in different ways to different types of users in an organization); (ii) using the RAG engine (119), interpret human/user queries/interactions, retrieve necessary information, and present responses to a corresponding user in a context-appropriate manner (in order to provide collaborative and non-compromised outcomes for the user); and/or (iii) using the RAG engine (119), ensure that different types of DTs can support real-time querying for tailored user insights.

In one or more embodiments, the RAG engine (119) may further include functionality to, e.g.,: (i) obtain (or receive) data (e.g., any type and/or quantity of input) from any source (e.g., a user via a client (e.g., 110A, FIG. 1.1A)) (and, if necessary, aggregate the data); (ii) based on (i) and by employing a set of linear, non-linear, and/or ML models, analyze, for example, a query to derive additional data; (iii) encompass hardware and/or software components and functionalities provided by the report engine (117) to operate as a service over the network so that the RAG engine (119) may be used externally; (iv) employ a set of subroutine definitions, protocols, and/or hardware/software components for enabling/facilitating communications between, for example, a UI (e.g., 118A, 118N, etc.) and external entities (e.g., users, administrators, etc.); (v) by generating one or more visual elements (through UIs/dashboards (126)), allow an administrator to, at least, interact with a user of a corresponding client; and/or (vi) concurrently display one or more separate windows on a related UI.

In one or more embodiments, on a UI (e.g., 118A, 118N, etc.), (i) each data item may be displayed (e.g., highlighted, visually indicated, etc.) with a different color (e.g., red color tones may represent a negative overall state of a server, green color tones may represent a positive overall state of a server, etc.) and (ii) one or more useful insights with respect to, at least, a carbon footprint of an entity (e.g., a server, an IHS, etc.) may be displayed in a separate window(s) to assist a related user while interpreting the insights (e.g., to help the user with respect to understanding the benefits and trade-offs of selecting different server options to execute a workload).

One of ordinary skill will appreciate that the report engine (117) may perform other functionalities without departing from the scope of the embodiments disclosed herein. The report engine (117) may be implemented as a computing device using hardware (e.g., any number of integrated circuits for processing computer readable instructions), software (e.g., a computer program), or any combination thereof. In one or more embodiments, the report engine (117) may be configured to perform all, or a portion, of the functionalities described in FIG. 2.3-2.4 and 4.4-4.5.

Turning now to FIG. 1.3, FIG. 1.3 shows a diagram of the DTCSM (102) in accordance with one or more embodiments disclosed herein. More specifically, FIG. 1.3 shows additional details of the DTCSM (102) in accordance with one or more embodiments disclosed herein. As being a physical computing device or a logical computing device, the DTCSM (102) may include functionality for generating, storing, updating, providing, and/or otherwise using diverse operational digital twins (where each digital twin is associated with an entity) (e.g., Workload DT A (167A), Workload DT N (167N), Server DT A (168A), Server DT N (168N), IHS DT A (160A), IHS DT N (160N), etc.). The DTCSM (102) may further include a set of DT creation templates (165) (refer to FIG. 1.4) and a DT manager (166) to perform, at least, the aforementioned functionalities. The DTCSM (102) may include additional, fewer, and/or different components without departing from the scope of the embodiments disclosed herein. Each component may be operably connected to any of the other components via any combination of wired and/or wireless connections.

In one or more embodiments, (a) Workload DT A (167A) may be a real-time digital/virtual representation of a workload (an instance of a defined class, in which the class specifies the information about the workload that is either required or would be stored, in addition to methods that enable an operation of Workload DT A), (b) Server DT A (168A) may be a real-time digital representation of a server (e.g., 112A, FIG. 1.2), and (c) IHS DT A (160A) may be a real-time digital representation of an IHS (e.g., 111A, FIG. 1.2) discussed throughout the present disclosure. As being a digital model, a digital twin (e.g., 167A, 168A, 160A, etc.) of a particular entity may include all relevant information about that entity (or represent said entity using standardized definitions, attributes, and/or other information).

In one or more embodiments, the DTCSM (102) may include an immutable ledger (e.g., a blockchain) to store each digital twin (e.g., 167A, 168A, 160A, etc.). As such, each digital twin snapshot (e.g., 181A, 181N, etc., FIG. 1.5) may be stored and prevent modification of the information stored in the given snapshot (while using data confidence fabric technologies to guarantee credibility and confidence of the information). In one or more embodiments, the DTCSM (102) may also be able to participate in a digital ledger outside of the embodiments disclosed herein, without including the entirety of the immutable ledger.

In one or more embodiments, before performing its duties, a digital twin (e.g., 167A, 168A, 160A, etc.) may first go through a modeling phase (performed by the DT manager (166) using performance models (e.g., 177, FIG. 1.4)) using training data (said another way, a digital twin may be a model based on specific modeling data that is decided by a corresponding organization). The modeling phase may be performed at different points-in-time, may be performed repeatedly (e.g., performing modeling, then monitoring, then modeling, then monitoring, etc.), or may otherwise be utilized to provide a digital twin's functionality.

In one or more embodiments, if a digital twin (that is generated and employed by a WS (e.g., 105, FIG. 1.2)) is not operating properly (e.g., is not providing the functionalities discussed along the application), the digital twin may be re-modeled using any form of training/trained data and/or the digital twin may be updated periodically as there are improvements in the underlying models (e.g., 177, FIG. 1.4). In one or more embodiments, in order to dynamically change/modify the digital twin's behavior, the trained data may be generated and provided by a set of linear, non-linear, and/or ML models.

One of ordinary skill will appreciate that the DT manager (166) may perform other functionalities without departing from the scope of the embodiments disclosed herein. The DT manager (166) may be implemented as a computing device using hardware (e.g., any number of integrated circuits for processing computer readable instructions), software (e.g., a computer program), or any combination thereof.

Referring to FIG. 1.3, an IHS DT (e.g., 160A) may include, for example (but not limited to): an IT-asset DT (e.g., 150A) (in which the IT-asset DT may include a server DT (e.g., 151A), a storage system DT (e.g., 199A), a networking system DT (e.g., 152A), etc.), a peripheral DT (e.g., 155A) (in which the peripheral DT may include a rack DT (e.g., 156A), a rack-mounted PDU DT (e.g., 157A), a backup power supply DT (e.g., 158A), etc.), a workload DT (e.g., 159A), etc.

Turning now to FIG. 1.4, FIG. 1.4 shows an example set of DT creation templates (165) in accordance with one or more embodiments disclosed herein. In one or more embodiments, the set of DT creation templates described in FIG. 1.4 is merely for illustrative purposes and is not intended to limit the scope of the embodiments disclosed herein.

In one or more embodiments, a DT creation template (e.g., 171A, 171N, etc.) may be used to generate a DT of an entity (e.g., 180A, FIG. 1.5), in which (i) the DT of the entity may include any number of snapshots (e.g., 181A, 181N, etc.) and (ii) each snapshot may include components of the DT creation template. Each DT snapshot may include additional, fewer, and/or different information without departing from the scope of the embodiments disclosed herein.

In one or more embodiments, a DT creation template/manifest (e.g., 171A, 171N, etc.) may include, at least, a set of definitions (172), a set of configurations (173), a set of static attributes (174), a set of dynamic attributes (175), a set of methods (176), and a set of performance models (177). In one or more embodiments, a definition of the definitions (172) may be a standardized data structure (e.g., the Digital Twins Definition Language (DTDL)) that defines the entity (e.g., a workload, a server, an IHS, etc.) of a related DT. The definition may include, for example, an identifier of the entity, a type of computing device(s) used to define the entity, and/or other information used to identify and/or define the entity.

Further, the definition may be made up of a set of metamodel classes that are used to define the behavior of a corresponding DT, in which the main metamodel classes that describe the behavior are the interface class, the command class, the component class, the property class, the relationship class, and the telemetry class. When a DT is modeled using its definition, the DT's behaviors may be defined using the aforementioned metamodel classes and the DT may implement its behavior/functionality using a software development kit in terms of these classes.

In one or more embodiments, a configuration of the configurations (173) may be a configuration of an entity during the corresponding point-in-time of a snapshot. For example, for a DT of a server, configurations may specify an OS of the server, configurations of the computing resources of the server, and/or any other configurations of the server at the corresponding point-in-time.

In one or more embodiments, the set of static attributes (174) may include additional attributes (e.g., a carbon footprint of a server) of the corresponding entity not intending to change between each snapshot. Conversely, the set of dynamic attributes (175) may include attributes that may change between each snapshot such as, for example, configuration changes, simulated hardware component degradation, simulated grid emissions caused by a DT, and other simulated performance metrics of the corresponding entity based on any use of the DT when executing other workloads.

In one or more embodiments, a DT (e.g., 180A, FIG. 1.5) may include the code necessary to execute specific methods (176) on or using the DT. This may be the case, if, for example, predictive ML model code is associated with a specific DT, but where full exposure of the predictive ML model code is undesired. In this case, the code may specify the means for accessing a specific method but may hide the actual method (for itself). In one or more embodiments, the set of methods (176) may keep a related DT in sync with the actual entity.

Further, the set of performance models (177) may include predictive models that indicate how a related entity (e.g., a workload) would behave, in which, for example, based on the performance models, the WS (e.g., 105, FIG. 1.2) may infer a timeframe within which the workload should be executed.

Turning now to FIG. 1.5, FIG. 1.5 shows an example DT of an entity in accordance with one or more embodiments disclosed herein. In one or more embodiments, the DT of the entity described in FIG. 1.5 is merely for illustrative purposes and is not intended to limit the scope of the embodiments disclosed herein.

In one or more embodiments, a DT (e.g., 180A) of a particular entity may include any number of snapshots (e.g., 181A, 181N, etc.). Each DT snapshot may correspond to a related DT at a given point-in-time.

In one or more embodiments, a WOS (e.g., 103, FIG. 1.2) may generate the DT (e.g., 167A, FIG. 1.3) using, at least, definitions, configurations, performance models, and static information associated with the DT. The WOS may then perform performance and behavioral modeling of the DT using one or more ML models and execution of one or more workloads (on a related server) to obtain performance metrics. The WOS may store the performance metrics (to the DTCSM (e.g., 102, FIG. 1.3)) as entity dynamic attributes corresponding to a DT snapshot (e.g., 181A) of the DT. Thereafter, the WOS may update the DT based on the performance metrics and based on any performance models generated from the performance and behavioral modeling.

FIG. 2.1-2.4 show a method for managing a workload in accordance with one or more embodiments disclosed herein. While various steps in the method are presented and described sequentially, those skilled in the art will appreciate that some or all of the steps may be executed in different orders, may be combined or omitted, and some or all steps may be executed in parallel without departing from the scope of the embodiments disclosed herein.

In one or more embodiments, the method described in FIG. 2.1-2.4 may support multiple users (of the same client or different clients) to send and manage their workloads simultaneously, in which each workload may be queued and prioritized based on the workload's specific requirements, real-time internal factors data, and/or real-time external/environmental factors data.

Turning now FIG. 2.1, FIG. 2.1 shows a workflow of a WIE (e.g., 104, FIG. 1.2) (for a single IHS) in accordance with one or more embodiments disclosed herein. Other components of the system (100) illustrated in FIG. 1.1B may also execute all or part of the workflow shown in FIG. 2.1 without departing from the scope of the embodiments disclosed herein.

In Step 200, the WIE receives a workload execution request (for a workload) from a user of a client (e.g., 110A, FIG. 1.1) or an AI agent (e.g., 109, FIG. 1.1A), in which the request may specify information related to the workload that needs to be executed and user credentials. In one or more embodiments, the information may include/specify, for example (but not limited to): an identifier of the user, a role of the user, a size of the workload, IP address details of the client, prioritization requirements for the workload (in which the user may want the workload to be executed in accordance with one or more of the prioritization requirements), computing resources that need to be assigned to execute the workload, a timeframe within which the workload needs to be executed, a type of electricity generation resource that needs to be prioritized while executing the workload, an execution urgency of the workload, etc. In other embodiments, the execution urgency of the workload may not be specified in the information.

In one or more embodiments, prioritization requirements for the workload may include, for example (but not limited to): a completion time prioritization (e.g., a workload runtime requirement that needs to be satisfied), a computing resource cost prioritization (e.g., a cost prioritization requirement), a power generation source prioritization (e.g., the user may have a preference for a power generation resource that should support the execution of the workload), a minimizing grid emissions prioritization (e.g., a carbon prioritization requirement), etc.

In one or more embodiments, by specifying the prioritization/optimization requirements/goals for the workload, the user may want to express that he/she wants to prioritize the workload, for example, against the cost of computing resource, the cost of energy, minimizing the carbon footprint of the server (that would be executing the workload), etc.

In Step 202, upon receipt of the request and by employing a set of linear models, non-linear models, and/or ML models, the WIE (i) analyzes the information to infer the execution urgency of the workload and (ii) request a relevant workload DT creation template from the DTCSM (e.g., 102, FIG. 1.3). In Step 204, the WIE receives the workload DT creation template from the DTCSM. In Step 206, by employing a set of linear models, non-linear models, and/or ML models, the WIE generates a workload DT for the request (more specifically, for the workload) using the workload DT creation template. In Step 208, the WIE sends a workload scheduling request to the WS (e.g., 105, FIG. 1.2) of the IHS by referencing the workload DT (e.g., 167A, FIG. 1.3). In one or more embodiments, the workflow may end following Step 208.

Turning now FIG. 2.2, FIG. 2.2 shows a workflow of the WS in accordance with one or more embodiments disclosed herein. Other components of the system (100) illustrated in FIG. 1.1B may also execute all or part of the workflow shown in FIG. 2.2 without departing from the scope of the embodiments disclosed herein.

In Step 210, the WS receives a workload scheduling request from either the WIE or an AI agent, in which the request includes all the necessary data (e.g., the execution urgency, credentials, information (or the original request), priority information, static data/attributes, dynamic data, any relevant methods and performance models, etc.) which includes all data necessary to characterize the workload. In Step 212, upon receipt of the request, the WS obtains/retrieves (i) active server DTs from the hardware management system (e.g., 140, FIG. 1.2) of the IHS, (ii) policy information from the policy engine (e.g., 120, FIG. 1.2) of the IHS, (iii) internal factors data from the IFDCT (e.g., 121, FIG. 1.2), (iv) external factors data from the EFDCT (e.g., 122, FIG. 1.2), and (v) historical data associated with the workload (or with a second workload that is similar to the workload) from the database (e.g., 101, FIG. 1.1B).

In one or more embodiments, real-time (or near real-time) internal factors data may include/specify, for example (but not limited to): a hardware viability of a first computing resource of a server, a hardware viability of a second computing resource of the server, information with respect to power distribution losses that occur in an IHS that is hosting the server, cooling and heating resource capabilities of the server, cooling and heating resource capabilities of the IHS, cooling/heating system energy requirements of the IHS, information with respect to a hardware resource set of the server, information indicating a number of workloads assigned to the server, an execution urgency of each of the workloads assigned to the server, a power usage effectiveness (PUE) value of the IHS, a geographic location of the IHS in the world, computing resource utilization data related to the server, an overall health of the server (e.g., healthy, unhealthy, etc.), internal temperature data of the IHS, rack-specific metrics related to the IHS (e.g., the direct cooling capability of the IHS, the backup generator capability of the IHS, etc.), etc.

In one or more embodiments, a PUE value of a component (e.g., an IHS) may indicate how energy efficient the component is. For example, as an ideal case, if a PUE value of an IHS is equal to one, this means that the IHS uses 100% of input power that is provided to the IHS. In general, a PUE value of an IHS is, on average, 1.57 (e.g., 64% effectiveness).

In one or more embodiments, external factors data (e.g., data related to current (and/or future) environmental factors and power grid conditions, which may vary daily and may depend on the availability of renewable power resources and demands from other users) may specify data that is obtained from any external services (i.e., services external to an IHS that hosts the server, if any) that would be used for the execution of the workload.

Real-time (or near real-time) external factors data may include/specify, for example (but not limited to): an identifier of an external service/entity, forecasted average emissions data specifying average emissions (e.g., on a hour-to-hour basis, on a day-to-day basis, etc.) that would be released by a power grid (e.g., 120A, FIG. 1.1B) over a period of time, a first signal indicating a recent capacity increase in the power grid, a second signal indicating when a power restriction would occur on the power grid, a third signal indicating when a cost of getting electricity from the power grid would be the cheapest or the most expensive, information with respect to forecasted weather conditions in a geographic location that the server is located, information with respect to forecasted climate conditions in a geographic location that the server is located, information with respect to obtaining electricity from the power grid over a period of time, external temperature data of the IHS, information indicating from where (or from which power grid) the IHS is getting power, etc.

In one or more embodiments, forecasted average emissions data may be obtained from a management entity of the power grid and information with respect to forecasted weather conditions may be obtained from a weather conditions reporting entity.

As used herein, average emissions may represent total emissions from a set of electricity/power generation resources on the power grid divided by total electricity generated by the set of electricity generation resources (discussed above in reference to FIG. 1.1A).

In one or more embodiments, historical data may include/specify, for example (but not limited to): historical processing times of the workload (or the second workload), a server that executed the workload (or the second workload) previously, historical internal factors data associated with the server, historical external factors data associated with the server, previously reported grid conditions/profiles data (including brown-outs, power restrictions, etc.), a period of time within which the server executed a second workload previously scheduled by the workload scheduler, etc.

In Step 214, by employing a “trained” ML model (e.g., an optimizer ML model, a predictive ML model, a workload-specific forecasting model, etc.), the WS performs a set of dynamic simulations/emulations using (i) the workload DT and (ii) the active server DTs and (b) by considering (i) the information (at least the prioritization requirements for the workload), (ii) the policy information, (iii) the historical data associated with the workload, (iv) the internal factors data, and (v) the external factors data to (a) estimate/forecast performance and duration metrics (PDMs) (e.g., a timeframe within which the workload needs to be executed, maximum energy required to execute the workload, computing resources required to execute the workload, compute performance data, emissions production as a result of electricity and water use, etc.) of the workload and (b) determine (i) an active server or (ii) a set of servers that needs to execute the workload.

In one or more embodiments, (i) the workload may have separate components that are each assigned to a specific server(s) and (ii) the WS may schedule the workload to a server that is already executing other workloads.

In one or more embodiments, while performing the set of dynamic simulations, the WS may manage one or more workloads (that are received from one or more users) in terms of scheduling/deployment and characterization. To do that, the WS may manage multiple workloads by queuing, comparing, and prioritizing based on the internal factors data, external factors data, required time to complete a related workload, and estimates of workload runtime requirements, and make informed decisions to schedule each workload accordingly.

In Step 216, based on the set of simulations (performed in Step 214), the WS determines that a second server of the IHS should be executing the workload (so that the workload can be executed efficiently and timely while minimizing carbon emissions due to execution of the workload).

In one or more embodiments, the second server may be selected (by the WS), for example (but not limited to): to satisfy a prioritization requirement set by the user, to manage other (more) urgent workloads, to help the energy demand profile of a corresponding power grid, to better align the workload with renewable power resource generators availability (e.g., during the day, during the week, etc.), to enable the use of renewable power generation resources to execute the workload, to optimize cooling system efficiency (and other operational parameters) of the IHS, as the grid emissions (e.g., average grid emissions) of the power grid (that provides electricity to the second server) indicate a significant use of renewable resources, as the geographic location of the second server supports lower carbon emissions, as the second server is not a low-utilized server (executing the workload in a low-utilized server may cause a higher negative environmental impact(s)), as the second server has the required computing resource to execute the workload, etc.

In one or more embodiments, the IHS may be an on-premises computing device (e.g., an IHS that is located in the far edge region). In other embodiments, the IHS may be an edge computing device (e.g., an IHS that is located in the functional edge region).

In Step 218, based on Step 216 and the execution urgency of the workload, the WS makes a determination (in real-time or near real-time) as to whether the workload is an urgent workload (e.g., a mission-critical workload, a latency-sensitive workload, etc.) or a non-urgent workload. Accordingly, in one or more embodiments, if the result of the determination is YES, the method proceeds to Step 222. If the result of the determination is NO, the method proceeds to Step 220. In one or more embodiments, the workload may be an urgent workload if the user is a high-priority user (e.g., a department manager, the CFO, etc.).

In Step 222, as a result of the determination in Step 218 being YES, the WS schedules/assigns/places the workload to the WQ (e.g., 106, FIG. 1.2), by prioritizing the workload in the WQ (since the workload is identified as an urgent workload) and indicating that the second server should be executing the workload (immediately). In Step 220, as a result of the determination in Step 218 being NO, the WS places the workload to the WQ, after previously placed workloads listed in the WQ and by indicating that the second server should be executing the workload.

In view of this, (i) the second server may execute the workload after executing a second workload listed in the WQ (in which the second workload may be requested by a second user and scheduled to the second server), (ii) the second server may execute the workload when the power grid is operating at a lower energy cost (so that execution of the workload can be further optimized for lower carbon emissions), and/or (iii) the second server may execute the workload when grid emissions indicate significant use of renewable power generation resources.

In Step 224, after placing the workload to the WQ (or following Steps 220-222), the WS notifies (i) the WLM (e.g., 194, FIG. 1.2) of the IHS to indicate that the workload has been placed/scheduled into the WQ (and the WLM is now responsible to manage the workload) and (ii) a scheduling engine of the second server to indicate that the second server would be executing the workload (each server of the IHS may have a separate queue that describes what that server will be executing, in which the WS may still manage the separate queue). In one or more embodiments, the workflow may end following Step 224.

Turning now FIG. 2.3, FIG. 2.3 shows a workflow of the WLM and other related components of the IHS in accordance with one or more embodiments disclosed herein. Other components of the system (100) illustrated in FIG. 1.1B may also execute all or part of the workflow shown in FIG. 2.3 without departing from the scope of the embodiments disclosed herein. As indicated below (in FIG. 2.3-2.4), the WLM manages the execution lifecycle of the workload.

In Step 226, the WLM infers that the workload has been placed into the WQ. In Step 228, the WLM notifies the second server to execute the workload. Separately, based on Step 226, the WLM may enter a wait state (with respect to this workload). During the wait state, two actions may happen: (i) the appropriate time to execute the workload is reached, at which point the WLM signals the second server to start execution or (ii) the WLM receives a rescheduling notice from the WS (which may happen, for example, (a) when the WS received a priority request for a second workload and/or (b) if external factors data varies from what was predicted at the time the workload was originally scheduled), at this point, the WLM may return to the wait state (looking for the new execution time to be reached).

In Step 230, the WLM monitors (or tracks, in real-time) execution of the workload on the second server to obtain second information related to the workload (once the execution of the workload has been completed).

In one or more embodiments, each computing component/resource (of the second server) that is related to execution of the workload may be monitored. Specifically, the computing resources (of the second server) may be monitored to measure computing resource utilization (in the second server), measure computing resource performance metrics, measure power grid intensity information (associated with the power grid that provides electricity to the second server), calculate a timeframe of operation (of the workload), measure a carbon footprint of each computing resource (while executing the workload), and identify external services used for execution of the workload. Other information (e.g., identified weather conditions while executing the workload) related to the workload may also be obtained during the monitoring. Such calculated (or otherwise measured) information can be considered as the second information (e.g., a workload report) associated with the workload.

In one or more embodiments, power grid intensity information may include information calculated, or measured, about the grid emissions (e.g., average grid emissions) caused by powering the computing resources (of the second server) used to execute the workload. For example, power grid intensity information may be calculated by identifying a power resource used to power the computing resources, identifying a profile of the power resource (e.g., a type of power plant used to generate electricity), and measuring an amount of energy used to power/support the computing component utilization.

As discussed above, grid emissions caused by the workload may be calculated (or otherwise measured) based on the amount of computing resources used to execute the workload, an amount of electricity used to power the said amount of computing resources, and a power supply profile of the power grid used to supply the said amount of electricity.

In Step 231, based on Step 230 (and/or the second information), the WLM makes a determination (in real-time or near real-time) as to whether the second information complies with the PDMs (see Step 214 of FIG. 2.2) (e.g., if the ML model accurately predicted the results). Accordingly, in one or more embodiments, if the result of the determination is YES, the method proceeds to Step 232. If the result of the determination is NO, the method proceeds to Step 242 of FIG. 2.4.

In Step 232, as a result of the determination in Step 231 being YES, the WLM notifies the WS to indicate that the workload has been completed. In Step 233, upon receiving the notification, the WS (i) removes the workload from the WQ and (ii) based on the second information, updates the workload DT to obtain an updated workload DT (where no further changes are allowed to the workload). In Step 234, the WS provides the updated workload DT to (i) the WR (e.g., 108, FIG. 1.2) of the IHS (along with the credentials and a result of the workload) and (ii) the DTCSM, in which the WR further sends the updated workload DT, result, and credentials to the RE (e.g., 117, FIG. 1.2) of the IHS.

In one or more embodiments, the WS may provide the second information to the DTCSM to update, at least, the DT of the workload (e.g., to reflect execution result of the workload to the DT of the workload). In one or more embodiments, the “updated” DT of the workload may then be used while, for example, fine-tuning the ML model(s) (used in Step 214 of FIG. 2.2) to generate updated ML models for better forecasting where to schedule a given workload.

In Step 236, the RE retrieves an updated DT of the second server from the hardware management system (e.g., 140, FIG. 1.2) of the IHS. In Step 238, the RE identifies, based on the user credentials, a level/role of the user (e.g., an executive person, a data center operator, a business unit leader, an entry-level engineer, etc.).

In Step 240, based on the role, the RE initiates displaying of, at least, the second information, the updated workload DT, the updated DT of the second server, information on energy usage of the second server, and an identified overall health status of the second server to the user using a role-specific UI/dashboard (e.g., 118A, FIG. 1.2). As indicated, using a corresponding UI, the RE presents and contextualizes information in accordance with the user's “operational” role/level. In one or more embodiments, the method may end following Step 240.

Turning now FIG. 2.4, FIG. 2.4 shows a workflow of the WLM and other related components of the IHS in accordance with one or more embodiments disclosed herein. Other components of the system (100) illustrated in FIG. 1.1B may also execute all or part of the workflow shown in FIG. 2.4 without departing from the scope of the embodiments disclosed herein.

In Step 242, as a result of the determination in Step 231 of FIG. 2.3 being NO, the WLM notifies the WS to indicate that the workload has been completed. In Step 244, upon receiving the notification, the WS (i) removes the workload from the WQ and (ii) based on the second information, updates the workload DT to obtain an updated workload DT (where no further changes are allowed to the workload). In Step 246, the WS provides the updated workload DT to (i) the WR of the IHS (along with the credentials and a result of the workload) and (ii) the DTCSM, in which the WR further sends the updated workload DT, result, and credentials to the RE of the IHS.

In Step 248, based on the second information, the DT manager (e.g., 166, FIG. 1.3) of the DTCSM updates (e.g., fine-tunes corresponding model parameters) the ML model(s) (used in Step 214 of FIG. 2.2) to generate one or more updated ML models for later use (e.g., to perform more reliable and actionable forecasting/predicting about where to schedule a given workload). Comparing to the ML models, the updated ML models'accuracy (in terms of producing better (or more accurate) forecasting outcomes) may be improved.

In Step 250, the RE retrieves an updated DT of the second server from the hardware management system of the IHS. In Step 252, the RE identifies, based on the user credentials, a level/role of the user (e.g., an executive person, a data center operator, a business unit leader, an entry-level engineer, etc.).

In Step 254, based on the role, the RE initiates displaying of, at least, the second information, the updated workload DT, the updated DT of the second server, information on energy usage of the second server, and an identified overall health status of the second server to the user using a role-specific UI/dashboard (e.g., 118A, FIG. 1.2). As indicated, using a corresponding UI, the RE presents and contextualizes information in accordance with the user's “operational” role/level. In one or more embodiments, the method may end following Step 254.

FIG. 3.1-3.2 show a workflow of a hardware management system of an IHS in accordance with one or more embodiments disclosed herein. While various steps in the method are presented and described sequentially, those skilled in the art will appreciate that some or all of the steps may be executed in different orders, may be combined or omitted, and some or all steps may be executed in parallel without departing from the scope of the embodiments disclosed herein.

Turning now FIG. 3.1, FIG. 3.1 shows a first part of the workflow in accordance with one or more embodiments disclosed herein. Other components of the system (100) illustrated in FIG. 1.1B may also execute all or part of the workflow shown in FIG. 3.1 without departing from the scope of the embodiments disclosed herein.

In Step 300, the IHS scheduler (e.g., 141, FIG. 1.2) of the IHS infers that the IHS is turned on by a user/administrator. In Step 302, the IHS scheduler analyzes/infers (i) one or more IT-assets that are part of the IHS, (ii) peripherals that are part of the IHS, and (iii) workloads that are assigned to the IHS. In Step 304, the IHS scheduler sends a request to the DTCSM to obtain a DT of each of the (i) IT-assets that are part of the IHS, (ii) peripherals that are part of the IHS, and (iii) workloads that are assigned to the IHS.

In Step 306, based on Step 304, the DT manager of the DTCSM makes a first determination (in real-time or near real-time) as to whether DTs of the requested entities exist. Accordingly, in one or more embodiments, if the result of the first determination is YES, the method proceeds to Step 312. If the result of the first determination is NO, the method proceeds to Step 308.

In Step 308, as a result of the first determination in Step 306 being NO, the IHS scheduler receives DT creation templates from the DT manager for the missing DTs. In Step 310, the IHS scheduler generates DTs of the missing DTs using corresponding DT creation templates. In Step 312, based on Step 310 or as a result of the first determination in Step 306 being YES, the IHS scheduler obtains existing DTs (for the aforementioned entities) from the DT manager. In Step 314, the IHS scheduler places/assigns the DTs (obtained and/or generated) to/as the active IHS DTs (e.g., 143, FIG. 1.2). Following Step 314, the method proceeds to Step 316 of FIG. 3.2.

Turning now FIG. 3.2, FIG. 3.2 shows a second part of the workflow in accordance with one or more embodiments disclosed herein. Other components of the system (100) illustrated in FIG. 1.1B may also execute all or part of the workflow shown in FIG. 3.2 without departing from the scope of the embodiments disclosed herein.

In Step 316, based on Step 314 of FIG. 3.1, the IHS scheduler makes a second determination (in real-time or near real-time) as to whether an IT-asset needs to be decommissioned from the IHS. Accordingly, in one or more embodiments, if the result of the second determination is YES, the method proceeds to Step 318. If the result of the second determination is NO, the method proceeds to Step 324.

In Step 318, as a result of the second determination in Step 316 being YES, the IHS scheduler turns off the IT-asset that would be decommissioned (e.g., for a relevant user of the IHS). In Step 320, the IHS scheduler turns off a related DT for the IT-asset and removes the related DT from the active IHS DTs. In Step 322, the IHS scheduler stores the related DT for the IT-asset to the database and/or to the DTCSM. In one or more embodiments, the method may end following Step 322.

In Step 324, as a result of the second determination in Step 316 being NO, the IHS scheduler makes a third determination (in real-time or near real-time) as to whether an IT-asset has been reconfigured (e.g., in terms of adding a hardware component to the IT-asset, removing a hardware component from the IT-asset, etc.). Accordingly, in one or more embodiments, if the result of the third determination is YES, the method proceeds to Step 326. If the result of the third determination is NO, the method may return to Step 316.

In Step 326, as a result of the third determination in Step 324 being YES, the IHS scheduler tests an updated DT of the IT-asset (which is generated due to the reconfiguration) using one or more benchmark tests (obtained from the database) to obtain test results. In Step 328, based on the test results, the IHS scheduler updates the related DT for the IT-asset to obtain an updated DT for the IT asset. In Step 330, the IHS scheduler places the updated DT for the IT-asset to the active IHS DTs for later use. In one or more embodiments, the method may end following Step 330.

FIG. 4.1-4.5 show a method for managing a workload in accordance with one or more embodiments disclosed herein. While various steps in the method are presented and described sequentially, those skilled in the art will appreciate that some or all of the steps may be executed in different orders, may be combined or omitted, and some or all steps may be executed in parallel without departing from the scope of the embodiments disclosed herein.

In one or more embodiments, the method described in FIG. 4.1-4.5 may support multiple users (of the same client or different clients) to send and manage their workloads simultaneously, in which each workload may be queued and prioritized based on the workload's specific requirements, real-time internal factors data, and/or real-time external/environmental factors data.

Turning now FIG. 4.1, FIG. 4.1 shows a workflow of a WIE (of a first IHS, located in a first geographic location in the world) (for multiple IHSs) in accordance with one or more embodiments disclosed herein. Other components of the system (100) illustrated in FIG. 1.1A may also execute all or part of the workflow shown in FIG. 4.1 without departing from the scope of the embodiments disclosed herein.

In Step 400, the WIE (of the first IHS) receives a workload execution request (for a workload) from a user of a client, an AI agent, the IIWS (e.g., 190, FIG. 1.1A), or a second WS (of a second IHS, located in a second geographic location in the world), in which the request may specify information related to the workload that needs to be executed and user credentials. In one or more embodiments, the information may include/specify, for example (but not limited to): an identifier of the user, a role of the user, a size of the workload, IP address details of the client, prioritization requirements for the workload (in which the user may want the workload to be executed in accordance with one or more of the prioritization requirements), computing resources that need to be assigned to execute the workload, a timeframe within which the workload needs to be executed, a type of electricity generation resource that needs to be prioritized while executing the workload, an execution urgency of the workload, etc. In other embodiments, the execution urgency of the workload may not be specified in the information.

In one or more embodiments, prioritization requirements for the workload may include, for example (but not limited to): a completion time prioritization (e.g., a workload runtime requirement that needs to be satisfied), a computing resource cost prioritization (e.g., a cost prioritization requirement), a power generation source prioritization (e.g., the user may have a preference for a power generation resource that should support the execution of the workload), a minimizing grid emissions prioritization (e.g., a carbon prioritization requirement), etc.

In one or more embodiments, by specifying the prioritization/optimization requirements/goals for the workload, the user may want to express that he/she wants to prioritize the workload, for example, against the cost of computing resource, the cost of energy, minimizing the carbon footprint of the server (that would be executing the workload), etc.

In Step 402, upon receipt of the request and by employing a set of linear models, non-linear models, and/or ML models, the WIE (i) analyzes the information to infer the execution urgency of the workload and (ii) request a relevant workload DT creation template from the DTCSM. In Step 404, the WIE receives the workload DT creation template from the DTCSM. In Step 406, by employing a set of linear models, non-linear models, and/or ML models, the WIE generates a workload DT for the request (more specifically, for the workload) using the workload DT creation template. In Step 408, the WIE sends a workload scheduling request to the WS (of the first IHS) by referencing the workload DT. In one or more embodiments, the workflow may end following Step 408.

Turning now FIG. 4.2, FIG. 4.2 shows a workflow of the WS (for multiple IHSs) in accordance with one or more embodiments disclosed herein. Other components of the system (100) illustrated in FIG. 1.1A may also execute all or part of the workflow shown in FIG. 4.2 without departing from the scope of the embodiments disclosed herein.

In Step 410, the WS (of the first IHS) receives a workload scheduling request from either the WIE (of the first IHS), the AI agent, or the IIWS, in which the request includes all the necessary data (e.g., the execution urgency, credentials, information (or the original request), priority information, static data/attributes, dynamic data, any relevant methods and performance models, etc.) which includes all data necessary to characterize the workload. In Step 412, upon receipt of the request, the WS obtains/retrieves (i) first active server DTs (on the first IHS) from the hardware management system (of the first IHS), (ii) first policy information from the policy engine (of the first IHS), (iii) first internal factors data (e.g., associated with a first server of the first IHS) from the IFDCT (of the first IHS), (iv) first external factors data (e.g., associated with the first server) from the EFDCT (of the first IHS), and (v) historical data associated with the workload (or with a second workload that is similar to the workload) from the database.

In Step 414, the WS provides the first active server DTs, first policy information, first internal factors data, first external factors data, execution urgency, a copy of the workload DT, and historical data to the IIWS. In one or more embodiments, the workflow may end following Step 414.

Turning now FIG. 4.3, FIG. 4.3 shows a workflow of the IIWS (for multiple IHSs) in accordance with one or more embodiments disclosed herein. Other components of the system (100) illustrated in FIG. 1.1A may also execute all or part of the workflow shown in FIG. 4.3 without departing from the scope of the embodiments disclosed herein.

In Step 416, the IIWS obtains/retrieves (i) second active server DTs (on the second IHS) from the hardware management system (of the second IHS), (ii) second policy information from the policy engine (of the second IHS), (iii) second internal factors data (e.g., associated with a the second server of the second IHS) from the IFDCT (of the second IHS), and (iv) second external factors data (e.g., associated with the second server) from the EFDCT (of the second IHS).

In Step 418, by employing a “trained” ML model (e.g., an optimizer ML model, a predictive ML model, a workload-specific forecasting model, etc.), the IIWS performs a set of dynamic simulations/emulations using the workload DT, data received from the first IHS and second IHS, the historical data associated with the workload, and by considering at least the prioritization requirements for the workload to (a) estimate/forecast PDMs of the workload and (b) determine (i) an active server or (ii) a set of servers that needs to execute the workload (by considering the cost of transferring the workload to a corresponding server(s)).

In one or more embodiments, (i) the workload may have separate components that are each assigned to a specific server(s) and (ii) the IIWS may schedule the workload to a server that is already executing other workloads.

In one or more embodiments, while performing the set of dynamic simulations, the IIWS may manage one or more workloads (that are received from one or more users) in terms of scheduling/deployment and characterization. To do that, the IIWS may manage multiple workloads by queuing, comparing, and prioritizing based on the internal factors data, external factors data, required time to complete a related workload, and estimates of workload runtime requirements, and make informed decisions to schedule each workload accordingly.

In Step 420, based on the set of simulations (performed in Step 418), the IIWS determines that the second server of the second IHS should be executing the workload (so that the workload can be executed efficiently and timely while minimizing carbon emissions due to execution of the workload). Based on this determination, the WS (of the first IHS) may note the transfer of the workload (or the workload DT) (either directly or through the IIWS) to the second IHS that should manage the workload.

In one or more embodiments, the second server (of the second IHS) may be selected, for example (but not limited to): to satisfy a prioritization requirement set by the user, to manage other (more) urgent workloads, to help the energy demand profile of a corresponding power grid, to better align the workload with renewable power resource generators availability (e.g., during the day, during the week, etc.), to leverage free cooling provided by a geographic location that the second server is located (so that (i) energy pricing/cost associated with executing the workload can be minimized (for sustainable energy consumption), (ii) carbon emissions caused by executing the workload can be minimized, and/or (iii) operational costs of the workload can be minimized), to enable the use of renewable power generation resources to execute the workload, to optimize cooling system efficiency (and other operational parameters) of the first IHS (that hosts the first server), as the cooling system overhead of the second IHS (that hosts the second server) is significantly lower than average, as the grid emissions (e.g., average grid emissions) of the power grid (that provides electricity to the second server) indicate a significant use of renewable resources, as the geographic location of the second server supports lower carbon emissions, as the second server is not a low-utilized server (executing the workload in a low-utilized server may cause a higher negative environmental impact(s)), as the second server has the required computing resource to execute the workload, etc.

In one or more embodiments, (a) the power grid (e.g., 120A, FIG. 1.1A) and the first server (of the first IHS (e.g., 111A, FIG. 1.1A)) may be located in the first geographic location in the world, (b) a second power grid (e.g., 120B, FIG. 1.1A) and the second server (of the second IHS (e.g., 111N, FIG. 1.1A)) may be located in the second geographic location in the world, and (c) the power grid may provide electricity to the first server and the client (that is being used by the user).

Further, the first IHS may be an on-premises computing device (e.g., an IHS that is located in the far edge region) and the second IHS may be an edge computing device (e.g., an IHS that is located in the functional edge region).

In Step 422, based on Step 420 (e.g., workload location shifting) and the execution urgency of the workload, the IIWS makes a determination (in real-time or near real-time) as to whether the workload is an urgent workload (e.g., a mission-critical workload, a latency-sensitive workload, etc.) or a non-urgent workload. Accordingly, in one or more embodiments, if the result of the determination is YES, the method proceeds to Step 426. If the result of the determination is NO, the method proceeds to Step 424. In one or more embodiments, the workload may be an urgent workload if the user is a high-priority user (e.g., a department manager, the CFO, etc.).

In Step 426, as a result of the determination in Step 422 being YES, the IIWS schedules/assigns/places the workload to the WQ (of the second IHS), by prioritizing the workload in the WQ (since the workload is identified as an urgent workload) and indicating that the second server should be executing the workload (immediately). In Step 424, as a result of the determination in Step 422 being NO, the IIWS places the workload to the WQ (of the second IHS), after previously placed workloads listed in the WQ and by indicating that the second server should be executing the workload.

In view of this, (i) the second server may execute the workload after executing a second workload listed in the WQ (in which the second workload may be requested by a second user and scheduled to the second server), (ii) the second server may execute the workload when the power grid is operating at a lower energy cost (so that execution of the workload can be further optimized for lower carbon emissions), and/or (iii) the second server may execute the workload when grid emissions indicate significant use of renewable power generation resources.

In Step 428, after placing the workload to the WQ (or following Steps 424-426), the IIWS notifies (i) the WLM (of the second IHS) to indicate that the workload has been placed/scheduled into the WQ of the second IHS (and the WLM of the second IHS is now responsible to manage the workload) and (ii) a scheduling engine of the second server to indicate that the second server would be executing the workload, and provides the PDMs to the WLM of the second IHS. In one or more embodiments, the workflow may end following Step 428.

Turning now FIG. 4.4, FIG. 4.4 shows a workflow of the WLM and other related components of the second IHS in accordance with one or more embodiments disclosed herein. Other components of the system (100) illustrated in FIG. 1.1A may also execute all or part of the workflow shown in FIG. 4.4 without departing from the scope of the embodiments disclosed herein. As indicated below (in FIG. 4.4-4.5), the WLM manages the execution lifecycle of the workload.

In Step 430, the WLM (of the second IHS) infers that the workload has been placed into the WQ (of the second IHS). In Step 432, the WLM notifies the second server (of the second IHS) to execute the workload. Separately, based on Step 430, the WLM (of the second IHS) may enter a wait state (with respect to this workload). During the wait state, two actions may happen: (i) the appropriate time to execute the workload is reached, at which point the WLM signals the second server to start execution or (ii) the WLM receives a rescheduling notice from the WS of the second IHS (which may happen, for example, (a) when the WS received a priority request for a second workload and/or (b) if external factors data varies from what was predicted at the time the workload was originally scheduled), at this point, the WLM may return to the wait state (looking for the new execution time to be reached).

In Step 434, the WLM (of the second IHS) monitors (or tracks, in real-time) execution of the workload on the second server (of the second IHS) to obtain second information related to the workload (once the execution of the workload has been completed). Details of the monitoring are described above in reference to Step 230 of FIG. 2.3.

In Step 436, based on Step 434 (and/or the second information), the WLM makes a determination (in real-time or near real-time) as to whether the second information complies with the PDMs. Accordingly, in one or more embodiments, if the result of the determination is YES, the method proceeds to Step 438. If the result of the determination is NO, the method proceeds to Step 450 of FIG. 4.5.

In Step 438, as a result of the determination in Step 436 being YES, the WLM notifies the WS to indicate that the workload has been completed. In Step 440, upon receiving the notification, the WS (i) removes the workload from the WQ, and (ii) sends the second information, an updated DT of the second server, and a result of the workload to the WS (of the first IHS). In Step 442, based on the second information, the WS (of the first IHS) updates the workload DT to obtain an updated workload DT (where no further changes are allowed to the workload).

In Step 444, the WS (of the first IHS) provides the updated workload DT to (i) the WR (of the first IHS) (along with the credentials, updated DT of the second server, second information, and result) and (ii) the DTCSM, in which the WR further sends the aforementioned data to the RE (of the first IHS). In one or more embodiments, the WS may provide the second information to the DTCSM to update, at least, the DT of the workload (e.g., to reflect execution result of the workload to the DT of the workload). In one or more embodiments, the “updated” DT of the workload may then be used while, for example, fine-tuning the ML model(s) to generate updated ML models for better forecasting where to schedule a given workload.

In Step 446, the RE (of the first IHS) identifies, based on the user credentials, a level/role of the user. In Step 448, based on the role, the RE (of the first IHS) initiates displaying of, at least, the second information, the updated workload DT, the updated DT of the second server, information on energy usage of the second server, and an identified overall health status of the second server to the user using a role-specific UI (e.g., 118A, FIG. 1.2). In one or more embodiments, the method may end following Step 448.

Turning now FIG. 4.5, FIG. 4.5 shows a workflow of the WLM and other related components of the IHS in accordance with one or more embodiments disclosed herein. Other components of the system (100) illustrated in FIG. 1.1A may also execute all or part of the workflow shown in FIG. 4.5 without departing from the scope of the embodiments disclosed herein.

In Step 450, as a result of the determination in Step 436 of FIG. 4.4 being NO, the WLM (of the second IHS) notifies the WS (of the second IHS) to indicate that the workload has been completed. In Step 452, upon receiving the notification, the WS (i) removes the workload from the WQ, and (ii) sends the second information, an updated DT of the second server, and a result of the workload to the WS (of the first IHS). In Step 454, based on the second information, the WS (of the first IHS) updates the workload DT to obtain an updated workload DT (where no further changes are allowed to the workload).

In Step 456, the WS (of the first IHS) provides the updated workload DT and the second information to (i) the WR (of the first IHS) (along with the credentials, updated DT of the second server, second information, and result) and (ii) the DTCSM, in which the WR further sends the aforementioned data to the RE (of the first IHS). In Step 458, based on the second information, the DT manager of the DTCSM updates the ML model(s) (used in Step 418 of FIG. 4.3) to generate one or more updated ML models for later use (e.g., to perform more reliable and actionable forecasting/predicting about where to schedule a given workload). Comparing to the ML models, the updated ML models'accuracy (in terms of producing better (or more accurate) forecasting outcomes) may be improved.

In Step 460, the RE (of the first IHS) identifies, based on the user credentials, a level/role of the user. In Step 462, based on the role, the RE (of the first IHS) initiates displaying of, at least, the second information, the updated workload DT, the updated DT of the second server, information on energy usage of the second server, and an identified overall health status of the second server to the user using a role-specific UI (e.g., 118A, FIG. 1.2). In one or more embodiments, the method may end following Step 462.

In one or more embodiments, in addition to the framework discussed in FIG. 4.1-4.5, other frameworks may be used to manage a workload in a system that hosts multiple IHSs. For example, a framework that includes multiple IHSs (that hosts no WSs) and an IIWS (external to all IHSs) may manage scheduling of a given workload. As yet another example, a framework that includes multiple IHSs (where each IHS hosts a WS) and an IIWS (external to all IHSs) may handle requests from various WSs to manage scheduling of a given workload.

As yet another example, a framework that includes multiple IHSs (where only one IHS does not host a WS) and an IIWS (internal to that IHS, replacing that IHS′ WS) may manage scheduling of a workload that is request by a user, in which the IIWS acts as a master WS. As yet another example, a framework that includes multiple IHSs and no separate IIWS, in which each WS may communicate with other WSs and the WS (receiving the initial workload request) may be responsible for the initial scheduling of the workload. The WS (that has received the request) may perform the initial scheduling by creating an AI agent with the task of identify scheduling options.

Turning now to FIG. 5, FIG. 5 shows a diagram of a computing device in accordance with one or more embodiments disclosed herein.

In one or more embodiments disclosed herein, the computing device (500) may include one or more computer processors (502), non-persistent storage (504) (e.g., volatile memory, such as RAM, cache memory), persistent storage (506) (e.g., a non-transitory computer readable medium, a hard disk, an optical drive such as a CD drive or a DVD drive, a Flash memory, etc.), a communication interface (512) (e.g., Bluetooth interface, infrared interface, network interface, optical interface, etc.), an input device(s) (510), an output device(s) (508), and numerous other elements (not shown) and functionalities. Each of these components is described below.

In one or more embodiments, the computer processor(s) (502) may be an integrated circuit for processing instructions. For example, the computer processor(s) (502) may be one or more cores or micro-cores of a processor. The computing device (500) may also include one or more input devices (510), such as a touchscreen, keyboard, mouse, microphone, touchpad, electronic pen, or any other type of input device. Further, the communication interface (512) may include an integrated circuit for connecting the computing device (500) to a network (e.g., a LAN, a WAN, Internet, mobile network, etc.) and/or to another device, such as another computing device.

In one or more embodiments, the computing device (500) may include one or more output devices (508), such as a screen (e.g., a liquid crystal display (LCD), plasma display, touchscreen, cathode ray tube (CRT) monitor, projector, or other display device), a printer, external storage, or any other output device. One or more of the output devices may be the same or different from the input device(s). The input and output device(s) may be locally or remotely connected to the computer processor(s) (502), non-persistent storage (504), and persistent storage (506). Many different types of computing devices exist, and the aforementioned input and output device(s) may take other forms.

The problems discussed throughout this application should be understood as being examples of problems solved by embodiments described herein, and the various embodiments should not be limited to solving the same/similar problems. The disclosed embodiments are broadly applicable to address a range of problems beyond those discussed herein.

One or more embodiments disclosed herein may be implemented using instructions executed by one or more processors of a computing device. Further, such instructions may correspond to computer readable instructions that are stored on one or more non-transitory computer readable mediums.

While embodiments discussed herein have been described with respect to a limited number of embodiments, those skilled in the art, having the benefit of this Detailed Description, will appreciate that other embodiments can be devised which do not depart from the scope of embodiments as disclosed herein. Accordingly, the scope of embodiments described herein should be limited only by the attached claims.

What is claimed is:

1. A method for managing a workload, the method comprising:
receiving, by a workload instantiation engine (WIE) of a first information handling system (IHS), a request for a workload from a user, wherein the request specifies information related to the workload;
analyzing, by the WIE, the information to infer an execution urgency of the workload;
providing, by the WIE, the request and the execution urgency to a workload scheduler (WS) of the first IHS;
obtaining, upon receipt of the request and by the WS, first active server digital twins (DTs) on the first IHS, and first internal factors data and first external factors data associated with a first server (FS) of the first IHS,
wherein the first external factors comprise forecasted average emissions data specifying average emissions that would be released by a power grid over a period of time,
providing, by the WS, the first active server DTs, the first internal factors data, and the first external factors data to an inter-IHS workload scheduler (IIWS);
obtaining, by the IIWS, second active server DTs on a second IHS, and second internal factors data and second external factors data associated with a second server (SS) of the second IHS;
performing, by the IIWS, a set of simulations:
using a model, data received from the first IHS and the second IHS, and
by considering the information and historical data associated with the workload to determine a server that needs to execute the workload and a set of metrics related to the workload;
determining, by the IIWS and based on the set of simulations, that the SS should be executing the workload;
based on the determining and the execution urgency, making, by the IIWS, a determination that the workload is a non-urgent workload; and
placing, by the IIWS and based on the determination, the workload to a workload queue (WQ) of the second IHS.

2. The method of claim 1, further comprising:
after placing the workload to the WQ:
monitoring, by a workload lifecycle manager (WLM) of the second IHS, execution of the workload on the SS to obtain second information related to the workload;
making, by the WLM and based on the second information, a second determination that the second information does not comply with the set of metrics, wherein the second information is provided to a DT manager;
updating, by the DT manager and based on the second information, the model to obtain an updated model;
after updating the model:
providing, by the WS, the second information, an updated workload DT, an updated DT of the SS, and a credential of the user to a report engine (RE) of the first IHS, wherein the request further specifies information related to the credential;
identifying, by the RE and based on the credential, a role of the user; and
initiating, by the RE and based on the role, displaying of the second information, the updated workload DT, and the updated DT of the SS to the user using a role-specific user interface.

3. The method of claim 1, wherein the information related to the workload specifies a timeframe within which the workload needs to be executed, a type of electricity generation resource that needs to be prioritized while executing the workload, a cost prioritization requirement, a carbon prioritization requirement, and the execution urgency of the workload.

4. The method of claim 1, wherein the first internal factors data comprises a hardware viability of a first computing resource of the FS, a hardware viability of a second computing resource of the FS, information with respect to power distribution losses that occur in the first IHS, cooling and heating resource capabilities of the FS, cooling and heating resource capabilities of the first IHS, information with respect to a hardware resource set of the FS, information indicating a number of workloads assigned to the FS, a second execution urgency of each of the workloads assigned to the FS, a power usage effectiveness (PUE) value of the first IHS, and a geographic location of the first IHS in the world.

5. The method of claim 1,
wherein the power grid and the FS are located in a first geographic location in the world,
wherein the SS is located in a second geographic location in the world, and
wherein the power grid provides electricity to the FS and a client that is being used by the user.

6. The method of claim 1,
wherein the first IHS is an on-premises computing device, and
wherein the second IHS is an edge computing device.

7. The method of claim 1, wherein the second external factors data comprises second forecasted average emissions data specifying average emissions that would be released by a second power grid over a period of time, a first signal indicating a recent capacity increase in the second power grid, a second signal indicating when a power restriction would occur on the second power grid, a third signal indicating when a cost of getting electricity from the second power grid would be the cheapest or the most expensive, and information with respect to forecasted weather conditions in a geographic location that the SS is located.

8. The method of claim 7,
wherein the second forecasted average emissions data is obtained from a management entity of the second power grid, and
wherein the information with respect to forecasted weather conditions is obtained from a weather conditions reporting entity.

9. The method of claim 1, wherein the average emissions represent total emissions from a set of electricity generation resources on the power grid divided by total electricity generated by the set of electricity generation resources.

10. The method of claim 9, wherein the set of electricity generation resources comprises a natural gas power plant, a solar farm, and a wind farm.

11. The method of claim 1, wherein the SS is selected in order to leverage free cooling provided by a geographic location that the SS is located.

12. The method of claim 1, wherein an active server DT of the first active server DTs is a virtual representation of the FS.

13. The method of claim 1, wherein the historical data specifies a period of time within which the SS executed a second workload, and wherein the second workload is similar to the workload.

14. The method of claim 1, wherein the set of metrics comprises a timeframe within which the workload needs to be executed, maximum energy required to execute the workload, and computing resources required to execute the workload.

15. The method of claim 1, wherein the SS executes the workload after executing a second workload listed in a workload queue of the second IHS, and wherein the second workload is requested by a second user and is scheduled to the SS.

16. The method of claim 1, wherein, to minimize energy cost of executing the workload and to minimize carbon emissions caused by executing the workload, the SS is selected to execute the workload.

17. A method for managing a workload, the method comprising:
receiving, by a workload instantiation engine (WIE) of a first information handling system (IHS), a request for a workload from a user, wherein the request specifies information related to the workload and a credential of the user;
analyzing, by the WIE, the information to infer an execution urgency of the workload;
providing, by the WIE, the request and the execution urgency to a workload scheduler (WS) of the first IHS;
obtaining, upon receipt of the request and by the WS, first active server digital twins (DTs) on the first IHS, and first internal factors data and first external factors data associated with a first server (FS) of the first IHS,
wherein the first external factors comprise forecasted average emissions data specifying average emissions that would be released by a power grid over a period of time,
providing, by the WS, the first active server DTs, the first internal factors data, and the first external factors data to an inter-IHS workload scheduler (IIWS);
obtaining, by the IIWS, second active server DTs on a second IHS, and second internal factors data and second external factors data associated with a second server (SS) of the second IHS;
performing, by the IIWS, a set of simulations:
using a model, data received from the first IHS and the second IHS, and
by considering the information and historical data associated with the workload to determine a server that needs to execute the workload and a set of metrics related to the workload;
determining, by the IIWS and based on the set of simulations, that the SS should be executing the workload;
based on the determining and the execution urgency, making, by the IIWS, a determination that the workload is an urgent workload; and
placing, by the IIWS and based on the determination, the workload to a workload queue (WQ) of the second IHS.

18. The method of claim 17, further comprising:
after placing the workload to the WQ:
monitoring, by a workload lifecycle manager (WLM) of the second IHS, execution of the workload on the SS to obtain second information related to the workload;
making, by the WLM and based on the second information, a second determination that the second information complies with the set of metrics;
after the second determination:
providing, by the WS, the second information, an updated workload DT, an updated DT of the SS, and the credential to a report engine (RE) of the first IHS;
identifying, by the RE and based on the credential, a role of the user; and
initiating, by the RE and based on the role, displaying of the second information, the updated workload DT, and the updated DT of the SS to the user using a role-specific user interface.

19. A system, the system comprising:
a workload instantiation engine (WIE) of a first information handling system (IHS) configured to:
receive a request for a workload from a user of a client, wherein the request specifies information related to the workload and a credential of the user;
analyze the information to infer an execution urgency of the workload;
provide the request and the execution urgency to a workload scheduler (WS) of the first IHS;
the WS configured to:
obtain, upon receipt of the request, first active server digital twins (DTs) on the first IHS, and first internal factors data and first external factors data associated with a first server (FS) of the first IHS,
wherein the first external factors comprise forecasted average emissions data specifying average emissions that would be released by a power grid over a period of time;
provide the first active server DTs, the first internal factors data, and the first external factors data to an inter-IHS workload scheduler (IIWS); and
the IIWS configured to:
obtain second active server DTs on a second IHS, and second internal factors data and second external factors data associated with a second server (SS) of the second IHS;
ternal factors data and second external factors data associated with the SS;
perform a set of simulations:
using a model, data received from the first IHS and the second IHS, and
by considering the information and historical data associated with the workload to determine a server that needs to execute the workload and a set of metrics related to the workload;
determine, based on the set of simulations, that the SS should be executing the workload;
make, based on the determining and the execution urgency, a determination that the workload is a non-urgent workload; and
place, based on the determination, the workload to a workload queue (WQ) of the second IHS.

20. The system of claim 19, wherein the average emissions represent total emissions from a set of electricity generation resources on the power grid divided by total electricity generated by the set of electricity generation resources.
